(19) United States
(12) Patent Application Publication
(10) Pub. No.: US 2025/0212657 A1
(43) Pub. Date: Jun. 26, 2025

(54) DISPLAY DEVICE, MANUFACTURING METHOD OF THE SAME, AND ELECTRONIC DEVICE

(71) Applicant: SAMSUNG DISPLAY CO., LTD., YONGIN-SI (KR)

(72) Inventors: JUNHONG PARK, Yongin-si (KR); JEONG WON KIM, Yongin-si (KR); KABJONG SEO, Yongin-si (KR)

(21) Appl. No.: 18/978,279

(22) Filed: Dec. 12, 2024

(30) Foreign Application Priority Data
Dec. 26, 2023 (KR) 10-2023-0191350

(51) Int. Cl. H10K 59/80; H10K 59/12; H10K 59/40

(52) U.S. Cl. CPC H10K 59/873; H10K 59/1201; H10K 59/40

(57) ABSTRACT

A display device includes a light emitting element layer including a light emitting element. An encapsulation layer is disposed on the light emitting element layer and covers the light emitting element. A sensing electrode is disposed on the encapsulation layer. A sensing insulating layer is disposed on the encapsulation layer. The sensing insulating layer has an upper surface. The sensing insulating layer includes a trench pattern recessed from the upper surface. A sensing line is disposed in the trench pattern. The sensing line is connected to the sensing electrode and includes a first metal layer.

### CROSS-REFERENCE TO RELATED APPLICATION

This application claims priority under 35 U.S.C. § 119 to Korean Patent Application No. 10-2023-0191350, filed on Dec. 26, 2023 in the Korean Intellectual Property Office, the disclosure of which is incorporated by reference in its entirety herein.

### 1. Technical Field

The disclosure relates to a display device, a method of manufacturing the display device, and an electronic device including the display device. More specifically, the disclosure relates to a display device which senses an external input, a method of manufacturing the display device, and an electronic device including the display device.

### 2. Discussion of Related Art

As information technology develops, the importance of a display device as a medium providing visual information to a user has increased.

Recently, display devices have been developed which include an input sensing layer to sense an external input. When a user touches the input sensing layer, an input signal is generated. The input signal is provided to a display panel. The display panel provides an image corresponding to the input signal to the user.

### SUMMARY

Embodiments provide a display device with increased display quality and reduced dead space.

Embodiments provide a method for manufacturing the display device.

Embodiments provide an electronic device including the display device.

According to an embodiment of the present disclosure, a display device includes a light emitting element layer including a light emitting element. An encapsulation layer is disposed on the light emitting element layer and covers the light emitting element. A sensing electrode is disposed on the encapsulation layer. A sensing insulating layer is disposed on the encapsulation layer. The sensing insulating layer has an upper surface. The sensing insulating layer includes a trench pattern recessed from the upper surface. A sensing line is disposed in the trench pattern. The sensing line is connected to the sensing electrode and includes a first metal layer.

In an embodiment, with respect to an upper surface of the encapsulation layer, a level of an upper surface of the first metal layer may be less than or equal to a level of the upper surface of the sensing insulating layer.

In an embodiment, the first metal layer may include copper (Cu).

In an embodiment, a line width of the first metal layer may be less than or equal to about 2.6 micrometers.

In an embodiment, an interval between at least two trenches defining the trench pattern may be less than or equal to about 4.0 micrometers.

In an embodiment, the sensing line may be selectively disposed on the encapsulation layer at a position where the trench pattern is defined.

In an embodiment, the trench pattern may be recessed from the upper surface of the sensing insulating layer to a point inside the sensing insulating layer between the upper surface of the sensing insulating layer and a lower surface of the sensing insulating layer.

In an embodiment, the display device may further include a protection pattern disposed on the first metal layer and covering an upper surface of the first metal layer.

In an embodiment, the protection pattern may be selectively disposed on the encapsulation layer at a position where the trench pattern is defined.

In an embodiment, the sensing line may further include a second metal layer covering a side surface of the first metal layer and a lower surface of the first metal layer and including a material different from a material of the first metal layer.

In an embodiment, the first metal layer, the second metal layer, and the protection pattern may be in direct contact with each other.

In an embodiment, the display device may further include a light blocking pattern disposed in the trench pattern and covering a side surface of the first metal layer and a lower surface of the first metal layer

In an embodiment, the light blocking pattern may include at least one material selected from a metal material and an organic material.

According to an embodiment of the present disclosure, a method of manufacturing a display device includes forming a lower sacrificial layer including a first material on a sensing insulating layer, and forming an upper sacrificial layer including a second material different from the first material on the lower sacrificial layer. An upper sacrificial pattern is formed by removing a portion of the upper sacrificial layer and a lower sacrificial pattern is formed by removing a portion of the lower sacrificial layer. A trench pattern is formed by removing a portion of the sensing insulating layer using the upper sacrificial pattern and the lower sacrificial pattern as a mask. An undercut structure is formed and is defined by the upper sacrificial pattern and the lower sacrificial pattern by removing a portion of the lower sacrificial pattern. A metal layer is formed in the trench pattern of the sensing insulating layer.

In an embodiment, the forming of the trench pattern may be performed by a first etching process. The forming of the undercut structure may be performed by a second etching process different from the first etching process. An etch rate of the lower sacrificial pattern for the second etching process may be greater than an etch rate of the upper sacrificial pattern for the second etching process.

In an embodiment, the first etching process may be a dry etching process, and the second etching process may be a wet etching process.

In an embodiment, the metal layer may be formed of copper (Cu).

In an embodiment, in the forming of the metal layer, a dummy metal layer including a same material as the metal layer may be formed on the upper sacrificial pattern, and the dummy metal layer may be formed discontinuously with the metal layer by the undercut structure.

In an embodiment, the method may further include forming a protection pattern on the metal layer covering an upper surface of the metal layer.

In an embodiment, in the forming of the protection pattern, a dummy protection pattern including a same material as the protection pattern may be formed on the dummy metal layer, and the dummy protection pattern may be formed discontinuously with the protection pattern by the undercut structure.

In an embodiment, the method may further include forming a photoresist pattern that covers the protection pattern and exposes the dummy protection pattern, removing the dummy protection pattern, the dummy metal layer, the upper sacrificial pattern, and the lower sacrificial pattern using the photoresist pattern as a mask, and removing the photoresist pattern.

In an embodiment, the method may further include forming a light blocking pattern in the trench pattern before the forming of the metal layer. In the forming of the light blocking pattern, a dummy light blocking pattern including a same material as the light blocking pattern may be formed on the upper sacrificial pattern. The dummy light blocking pattern may be formed discontinuously with the light blocking pattern by the undercut structure.

According to an embodiment of the present disclosure, a display device includes a display panel including a light emitting element layer having a light emitting element. An input sensing layer is on the display panel. The input sensing layer includes sensing electrodes, sensing lines and first and second sensing insulating layers. Each of the sensing lines includes a lower sensing line disposed on the first sensing insulating layer and an upper sensing line disposed on the second sensing insulating layer. The upper and lower sensing lines are connected to each other. At least one of: the lower sensing line is arranged in an engraved pattern in an upper surface of the first sensing insulating layer and the upper sensing line is arranged in an engraved pattern in an upper surface of the second sensing insulating layer.

In an embodiment, the lower sensing line is arranged in the engraved pattern in the upper surface of the first sensing insulating layer and the upper sensing line is arranged in the engraved pattern in the upper surface of the second sensing insulating layer.

In an embodiment, the lower sensing line and the upper sensing line are directly connected to each other through at least one contact hole defined in the second sensing insulating layer.

In an embodiment, the sensing electrodes include first sensing electrodes arranged along a first direction. The first sensing electrodes include first sensing parts and first connecting parts. The sensing electrodes further include second sensing electrodes arranged along a second direction crossing the first direction. The second sensing electrodes include second sensing parts and second connecting parts. At least some of the first sensing parts, the first connecting parts, the second sensing parts and the second connecting parts are arranged in an engraved pattern in the upper surface of the first sensing insulating layer or the upper surface of the second sensing insulating layer, respectively.

According to an embodiment of the present disclosure, an electronic device includes a display device and a power supply configured to provide power to the display device. The display device includes a light emitting element layer including a light emitting element. An encapsulation layer is disposed on the light emitting element layer and covers the light emitting element. A sensing electrode is disposed on the encapsulation layer. A sensing insulating layer is disposed on the encapsulation layer. The sensing insulating layer has an upper surface. The sensing insulating layer includes a trench pattern recessed from the upper surface. A sensing line is disposed in the trench pattern. The sensing line is connected to the sensing electrode and includes a first metal layer.

In the display device according to embodiments, a sensing line included in an input sensing layer may include a metal layer, and the metal layer of the sensing line may be disposed in a trench pattern defined in a sensing insulating layer. That is, the metal layer of the sensing line may be arranged in an engraved pattern rather than an embossed pattern with respect to the sensing insulating layer. Accordingly, during a process of forming the metal layer, empty space such as skew may not be generated in the metal layer. Therefore, the metal layer may be more easily implemented as a fine pattern. Accordingly, a display quality of the display device may be increased and dead space may be reduced.

Additionally, in a method of manufacturing a display device according to embodiments, the trench pattern may be formed in the sensing insulating layer, and sacrificial patterns may be formed on the sensing insulating layer to form an undercut structure. Accordingly, the metal layer may be automatically self-patterned upon deposition by the undercut structure and the trench pattern. For example, a separate etching process may not be performed to form the metal layer. Accordingly, empty space such as skew due to the etching process may not be generated in the metal layer. Therefore, the metal layer may be more easily formed into a fine pattern.

It is to be understood that both the foregoing general description and the following detailed description are non-limiting and are intended to provide further explanation of the present disclosure.

### BRIEF DESCRIPTION OF THE DRAWINGS

Illustrative, non-limiting embodiments of the present disclosure will be more clearly understood from the following detailed description taken in conjunction with the accompanying drawings.

FIG. 1 is a plan view illustrating a display device according to an embodiment of the present disclosure.

FIG. 2 is a cross-sectional view illustrating the display device of FIG. 1 according to an embodiment of the present disclosure.

FIG. 3 is a plan view illustrating the display panel of FIG. 2 according to an embodiment of the present disclosure.

FIG. 4 is a circuit diagram illustrating the pixel of the display panel of FIG. 3 according to an embodiment of the present disclosure.

FIG. 5 is a cross-sectional view illustrating the display panel of FIG. 2 according to an embodiment of the present disclosure.

FIG. 6 is a plan view illustrating the input sensing layer of FIG. 2 according to an embodiment of the present disclosure.

FIG. 7 is a cross-sectional view illustrating an example taken along line X-X′ of FIG. 6 according to an embodiment of the present disclosure.

FIG. 8 is a cross-sectional view illustrating an example taken along line Y-Y of FIG. 6 according to an embodiment of the present disclosure.

FIG. 9 is a cross-sectional view illustrating an example taken along line Y-Y of FIG. 6 according to an embodiment of the present disclosure.

FIG. 10 is a cross-sectional illustrating an example taken along line Y-Y of FIG. 6 according to an embodiment of the present disclosure.

FIGS. 11 to 23 are views illustrating a manufacturing method of the sensing line of FIG. 8 according to embodiments of the present disclosure.

FIG. 24 is a cross-sectional view illustrating an example taken along line Y-Y′ of FIG. 6 according to an embodiment of the present disclosure.

FIGS. 25 and 29 are views illustrating a manufacturing method of the sensing line of FIG. 24 according to embodiments of the present disclosure.

FIG. 30 is a cross-sectional view illustrating another example taken along line X-X′ of FIG. 6 according to an embodiment of the present disclosure.

FIG. 31 is a block diagram illustrating an electronic device according to an embodiment.

### DETAILED DESCRIPTION OF EMBODIMENTS

Hereinafter, display devices in accordance with embodiments of the present disclosure will be described in more detail with reference to the accompanying drawings. The same reference numerals are used for the same components in the drawings, and redundant descriptions of the same components may be omitted for economy of explanation.

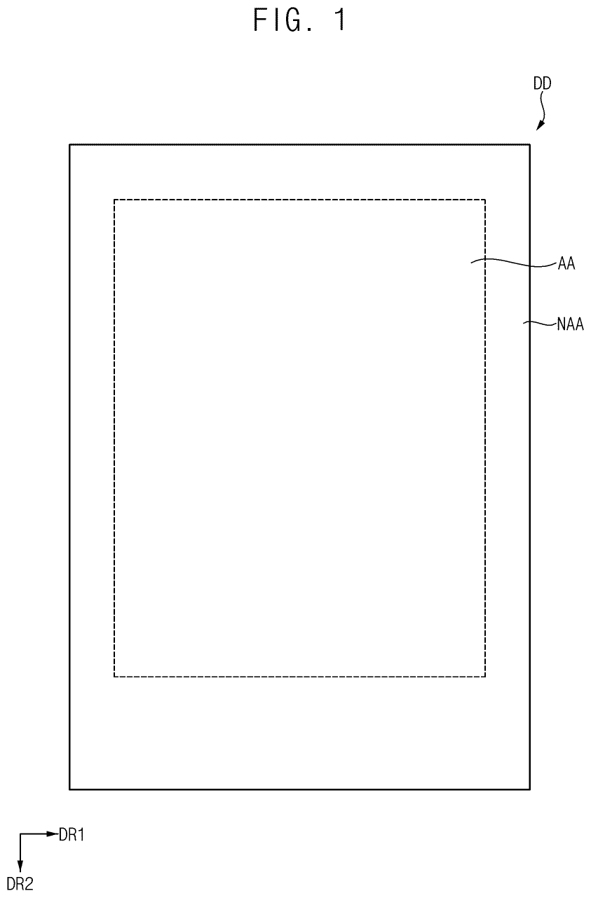

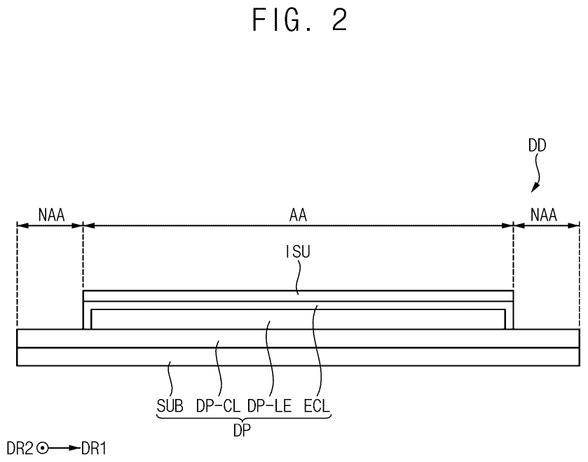

FIG. 1 is a plan view illustrating a display device according to an embodiment of the present disclosure, and FIG. 2 is a cross-sectional view illustrating the display device of FIG. 1.

Referring to FIGS. 1 and 2, a display device DD may include an active area AA and a non-active area NAA. The active area AA may be an area which generates light or displays an image by adjusting a transmittance of light provided from an external light source. The non-active area NAA may be an area which does not display images. The non-active area NAA may be located around the active area AA. For example, in an embodiment the non-active area NAA may entirely surround the active area AA (e.g., in the first and second directions DR1, DR2). However, embodiments of the present disclosure are not necessarily limited thereto. For example, in some embodiments the non-active area NAA may not surround at least one side of the active area AA.

In an embodiment, the display device DD may include a display panel DP and an input sensing layer ISU disposed on the display panel DP. The display panel DP may include a substrate SUB, a circuit element layer DP-CL, a light emitting element layer DP-LE, and an encapsulation layer ECL.

The substrate SUB may include a transparent or opaque material. In an embodiment, examples of materials that can be used as the substrate SUB may include glass, quartz, plastic, or the like. These materials can be used alone or in combination with each other.

The circuit element layer DP-CL may be disposed on (e.g., disposed directly thereon) the substrate SUB. The circuit element layer DP-CL may include a plurality of transistors. In an embodiment, each of the transistors may include a control terminal, an input terminal, and an output terminal. For example, the circuit element layer DP-CL may include transistors for driving a light emitting element.

In an embodiment, the circuit element layer DP-CL may include a semiconductor pattern, a conductive pattern, and a signal line. In some embodiments, an insulating layer, a semiconductor layer, and a conductive layer may be formed on the substrate SUB by coating, deposition, or the like, and the insulating layer, the semiconductor layer, and the conductive layer may be selectively patterned. Accordingly, the circuit element layer DP-CL including the semiconductor pattern, the conductive pattern, and the signal line may be formed on (e.g., formed directly thereon) the substrate SUB.

The light emitting element layer DP-LE may include a light emitting element. The light emitting element layer DP-LE is disposed on (e.g., disposed directly thereon) the circuit element layer DP-CL. The light emitting element layer DP-LE may further include an organic layer such as a pixel defining layer.

The encapsulation layer ECL may be disposed on (e.g., disposed directly thereon) the light emitting element layer DP-LE. The encapsulation layer ECL may cover the light emitting element. For example, the encapsulation layer ECL may protect the light emitting element from external moisture, heat, shock, or the like. In some embodiments, the encapsulation layer ECL may include a first inorganic encapsulation layer, an organic encapsulation layer disposed on the first inorganic encapsulation layer, and a second inorganic encapsulation layer disposed on the organic encapsulation layer. However, embodiments of the present disclosure are not necessarily limited thereto and the encapsulation layer ECL may have various different configurations which include at least one inorganic encapsulation layer and at least one organic encapsulation layer.

The input sensing layer ISU may be disposed on (e.g., disposed directly thereon) the encapsulation layer ECL. The input sensing layer ISU may sense an external input. The external input may be provided in various forms. For example, in some embodiments the external input may be in a form of a touch of a part of a user's body, pen touch, light, heat, or pressure. In addition, the external input may be in a form of a touch (e.g., hovering or proximity) in an adjacent space as well as a direct contact.

In an embodiment, the input sensing layer ISU may be disposed directly on the encapsulation layer ECL. As used herein, “component A is disposed directly on component B” means that no adhesive layer or other intervening element is disposed between component A and component B. In an embodiment, the input sensing layer ISU may be formed through a continuous process with the display panel DP. However, embodiments of the present disclosure are not necessarily limited thereto, and the input sensing layer ISU may be provided as an individual panel and bonded to the display panel DP through an adhesive layer in some embodiments.

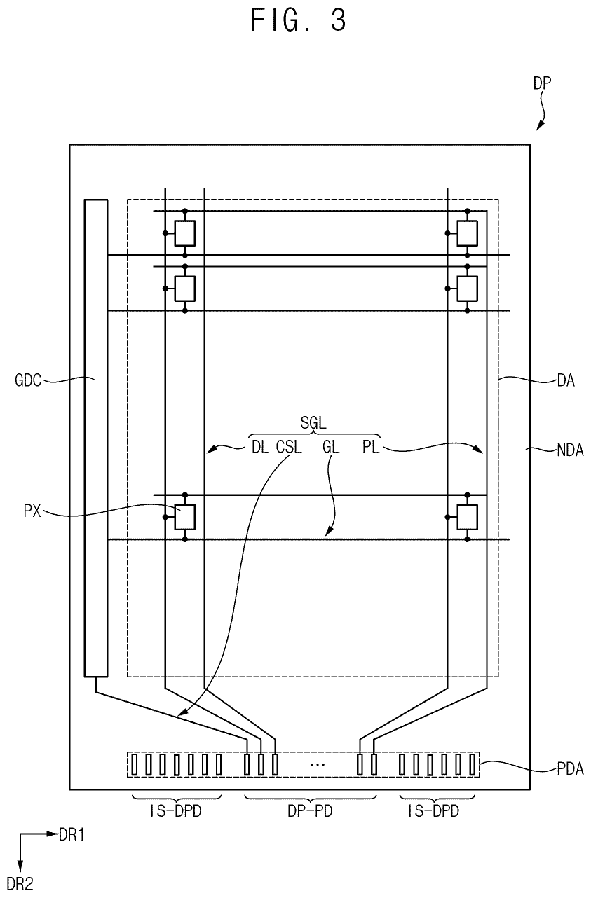

FIG. 3 is a plan view illustrating the display panel of FIG. 2.

Referring to FIG. 3, in a plan view, the display panel DP may be divided into a display area DA and a non-display area NDA. The non-display area NDA may surround the display area DA (e.g., in the first and second directions DR1, DR2). The display area DA and the non-display area NDA of the display panel DP may respectively correspond to the active area AA and the non-active area NAA of the display device DD of FIG. 1.

A pixel PX may be disposed in the display area DA. The pixel PX may include a light emitting element and a pixel circuit connected to the light emitting element. In an embodiment, a driving circuit GDC and a signal pad DP-PD may be disposed in the non-display area NDA. The pixel PX may be connected to the driving circuit GDC and the signal pad DP-PD through a signal line SGL. The driving circuit GDC, the signal line SGL, the signal pad DP-PD, and the pixel circuit may be included in the circuit element layer DP-CL illustrated in FIG. 2.

In an embodiment, the driving circuit GDC may include a plurality of transistors formed in the same process as the pixel circuit of the pixel PX. For example, the driving circuit GDC may include a gate driving circuit. The gate driving circuit may output a gate signal to a gate line GL, which will be described later.

In an embodiment, the signal line SGL may include the gate line GL, a data line DL, a power line PL, and a control signal line CSL. The gate line GL, the data line DL, and the power line PL may be connected to a corresponding pixel. The control signal line CSL may provide a control signal to the driving circuit GDC.

An area in the non-display area NDA where the signal pad DP-PD is disposed may be defined as a pad area PDA. In an embodiment, the pad area PDA may be bent from the display area DA and may contact a rear surface of the display panel DP. An external device (e.g., a circuit board, etc.) may be bonded to the pad area PDA.

The display panel DP may further include a dummy pad IS-DPD disposed in the pad area PDA. In an embodiment, the dummy pad IS-DPD may be formed through the same process as the signal line SGL. The dummy pad IS-DPD may be optionally provided in the display device DD including the input sensing layer ISU.

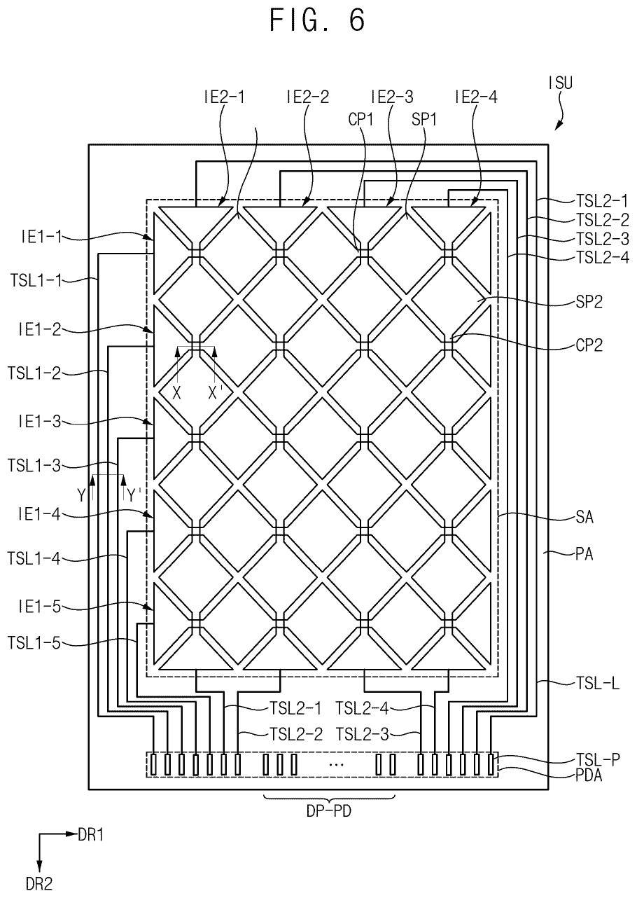

The dummy pad IS-DPD may overlap a pad part TSL-P of the input sensing layer ISU of FIG. 6, which will be described later. In an embodiment, the dummy pad IS-DPD may be a floating electrode.

In an embodiment, the display panel DP may further include at least one driving chip. The driving chip may be connected to the data line DL. Accordingly, the data line DL may be electrically connected to the signal pad DP-PD through the driving chip. Additionally, in an embodiment, the control signal line CSL and/or the power line PL may also be connected to the driving chip.

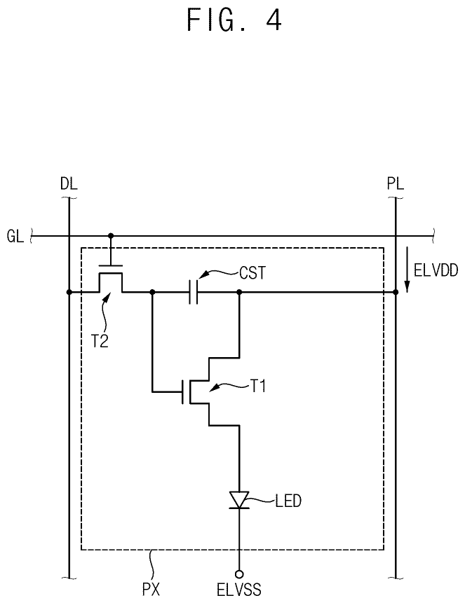

FIG. 4 is a circuit diagram illustrating the pixel of the display panel of FIG. 3.

FIG. 4 illustrates an example of a circuit diagram of the pixel PX of FIG. 3, and embodiments of the present disclosure are not necessarily limited thereto.

The pixel PX may include a light emitting element LED and the pixel circuit. In an embodiment, the pixel circuit may include a first transistor T1, a second transistor T2, and a capacitor CST. The pixel circuit may be electrically connected to the light emitting element LED and provide a driving current to the light emitting element LED.

In an embodiment, the first transistor T1 may include a control terminal, a first terminal (e.g., an input terminal), and a second terminal (e.g., an output terminal). The control terminal (e.g., a gate terminal) of the first transistor T1 may be connected to a first terminal of the capacitor CST. The control terminal of the first transistor T1 may be connected to the second transistor T2 to receive a data voltage. The first terminal of the first transistor T1 may be connected to a second terminal of the capacitor CST. The first terminal of the first transistor T1 may be connected to the power line PL to receive a high-power voltage ELVDD. The second terminal of the first transistor T1 may be connected to the light emitting element LED to provide the driving current. The first transistor T1 may generate the driving current based on a voltage difference between the control terminal and the first terminal.

In an embodiment, the second transistor T2 may include a control terminal, a first terminal (e.g., an input terminal), and a second terminal (e.g., an output terminal). The control terminal of the second transistor T2 may receive a gate signal through the gate line GL. The first terminal of the second transistor T2 may receive the data voltage through the data line DL. The second terminal of the second transistor T2 may provide the data voltage to the control terminal of the first transistor T1 while the second transistor T2 is turned on.

The capacitor CST may include the first terminal and a second terminal. The first terminal of the capacitor CST may be connected to the first transistor T1, and the second terminal of the capacitor CST may receive a high-power voltage ELVDD. The capacitor CST may maintain a voltage level of the control terminal of the first transistor T1 in a specific section.

In an embodiment, the light emitting element LED may include a first terminal (e.g., anode terminal) and a second terminal (e.g., cathode terminal). The first terminal of the light emitting element LED may be connected to the first transistor T1 to receive the driving current, and the second terminal may receive a low-power voltage ELVSS. The light emitting element LED may generate light having a brightness corresponding to the driving current.

As described above, FIG. 4 only illustrates an example of a circuit diagram of the pixel PX, and embodiments of the present disclosure are not necessarily limited thereto. The pixel PX may further include transistors and capacitors other than the first transistor T1, the second transistor T2, and the capacitor CST.

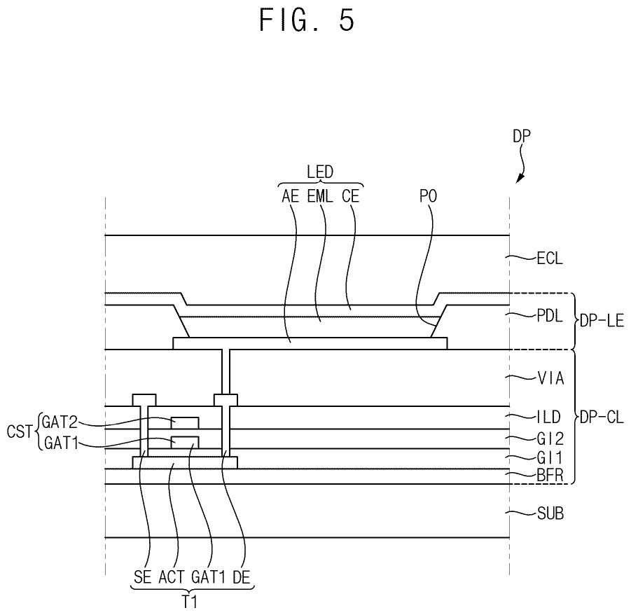

FIG. 5 is a cross-sectional view illustrating the display panel of FIG. 2.

Referring to FIG. 5, the circuit element layer DP-CL, the light emitting element layer DP-LE, and the encapsulation layer ECL may be disposed on the substrate SUB.

In an embodiment, the circuit element layer DP-CL may include a buffer layer BFR, a first gate insulating layer GI1, a second gate insulating layer GI2, an interlayer insulating layer ILD, a via insulating layer VIA, and the first transistor T1, and the capacitor CST. The first transistor T1 may include an active pattern ACT, a first gate electrode GAT1, an input electrode SE, and an output electrode DE. The capacitor CST may include the first gate electrode GAT1 and a second gate electrode GAT2.

In an embodiment, the light emitting element layer DP-LE may include the light emitting element LED and a pixel defining layer PDL. The light emitting element LED may include a pixel electrode AE, an emission layer EML, and a common electrode CE.

The buffer layer BFR may be disposed on the substrate SUB. For example, in an embodiment the buffer layer BFR may be disposed directly on an upper surface of the substrate SUB. The buffer layer BFR may prevent impurities such as oxygen and moisture from diffusing above the substrate SUB. In an embodiment, the buffer layer BFR may include an inorganic insulating material such as a silicon compound or metal oxide.

The active pattern ACT may be disposed on the buffer layer BFR. For example, in an embodiment the active pattern ACT may be disposed directly on an upper surface of the buffer layer BFR. In an embodiment, the active pattern ACT may include a silicon semiconductor material or an oxide semiconductor material.

The first gate insulating layer GI1 may be disposed on (e.g., disposed directly thereon) the buffer layer BFR. The first gate insulating layer GI1 may cover the active pattern ACT. The first gate insulating layer GI1 may include an inorganic insulating material.

The first gate electrode GAT1 may be disposed on the first gate insulating layer GI1. For example, in an embodiment, the first gate electrode GAT1 may be disposed directly on an upper surface of the first gate insulating layer GI1. The first gate electrode GAT1 may overlap the active pattern ACT in a plan view. In an embodiment, the first gate electrode GAT1 may include metal, alloy, conductive metal oxide, transparent conductive material, or the like.

The second gate insulating layer GI2 may be disposed on (e.g., disposed directly thereon) the first gate insulating layer GI1 and the first gate electrode GAT1. The second gate insulating layer GI2 may cover the first gate electrode GAT1. In an embodiment, the second gate insulating layer GI2 may include an inorganic insulating material.

The second gate electrode GAT2 may be disposed on the second gate insulating layer GI2. For example, in an embodiment the second gate electrode GAT2 may be disposed directly on an upper surface of the second gate insulating layer GI2. The second gate electrode GAT2 may overlap the first gate electrode GAT1 in a plan view. In an embodiment, the second gate electrode GAT2 may include metal, alloy, conductive metal oxide, transparent conductive material, or the like.

The interlayer insulating layer ILD may be disposed on (e.g., disposed directly thereon) the second gate insulating layer GI2 and the second gate electrode GAT2. The interlayer insulating layer ILD may cover the second gate electrode GAT2. In an embodiment, the interlayer insulating layer ILD may include an inorganic insulating material.

The input electrode SE and the output electrode DE may be disposed on the interlayer insulating layer ILD. For example, in an embodiment the input electrode SE and the output electrode DE may be disposed directly on an upper surface of the interlayer insulating layer ILD. In an embodiment, the input electrode SE and the output electrode DE may be connected to (e.g., directly connected thereto) the active pattern ACT through contact holes formed in the interlayer insulating layer ILD, the first gate insulating layers GI1, and the second gate insulating layer GI2. In an embodiment, the input electrode SE and the output electrode DE may include metal, alloy, conductive metal oxide, transparent conductive material, or the like.

The via insulating layer VIA may be disposed on (e.g., disposed directly thereon) the interlayer insulating layer ILD, the input electrode SE, and the output electrode DE. The via insulating layer VIA may cover the input electrode SE and the output electrode DE. In an embodiment, the via insulating layer VIA may include an organic insulating material.

The pixel electrode AE may be disposed on the via insulating layer VIA. For example, in an embodiment, the pixel electrode AE may be disposed directly on an upper surface of the via insulating layer VIA. In an embodiment, the pixel electrode AE may be electrically connected to the first transistor T1 through a contact hole formed in the via insulating layer VIA. In an embodiment, the pixel electrode AE may include metal, alloy, conductive metal oxide, transparent conductive material, or the like.

The pixel defining layer PDL may be disposed on the via insulating layer VIA. The pixel defining layer PDL may define a pixel opening PO which exposes a portion of the pixel electrode AE. For example, in an embodiment the pixel defining layer PDL may be disposed directly on lateral ends of the pixel electrode AE and may expose a central portion of the pixel electrode AE. In an embodiment, the pixel defining layer PDL may include an organic insulating material.

The emission layer EML may be disposed on the pixel electrode AE in the pixel opening PO. The emission layer EML may include a material which emits light. For example, in an embodiment the emission layer EML may include an organic light emitting material.

The common electrode CE may be disposed on the emission layer EML. In an embodiment, the common electrode CE may include a conductive material such as a metal, alloy, conductive metal nitride, conductive metal oxide, or transparent conductive material.

The encapsulation layer ECL may be disposed on (e.g., disposed directly thereon) the light emitting element layer DP-LE. The encapsulation layer ECL may cover the light emitting element LED. In an embodiment, the encapsulation layer ECL may include a first inorganic encapsulation layer, an organic encapsulation layer disposed on the first inorganic encapsulation layer, and a second inorganic encapsulation layer disposed on the organic encapsulation layer. However, embodiments of the present disclosure are not necessarily limited thereto.

FIG. 6 is a plan view illustrating the input sensing layer of FIG. 2.

Referring to FIG. 6, the input sensing layer ISU may include a sensing area SA which senses an external input, and a peripheral area PA located around the sensing area SA (e.g., in the first and second directions DR1, DR2).

The sensing area SA may correspond to the display area DA of the display panel DP and have an area (e.g., a planar size in the first and second directions DR1, DR2) substantially the same as or larger than an area (e.g., a planar size in the first and second directions DR1, DR2) of the display area DA. The peripheral area PA may surround the sensing area SA (e.g., in the first and second directions DR1, DR2). For example, the peripheral area PA may correspond to the non-display area NDA of the display panel DP.

In an embodiment, the input sensing layer ISU may include first sensing electrodes IE1-1, IE1-2, IE1-3, IE1-4, IE1-5 and second sensing electrodes IE2-1, IE2-2, IE2-3, IE2-4, first sensing lines TSL1-1, TSL1-2, TSL1-3, TSL1-4, TSL1-5, and second sensing lines TSL2-1, TSL2-2, TSL2-3, TSL2-4.

In an embodiment, the first sensing electrodes IE1-1, IE1-2, IE1-3, IE1-4, IE1-5 and the second sensing electrodes IE2-1, IE2-2, IE2-3, IE2-4 may be disposed in the sensing area SA, and the first sensing lines TSL1-1, TSL1-2, TSL1-3, TSL1-4, TSL1-5 and the second sensing lines TSL2-1, TSL2-2, TSL2-3, TSL2-4 may be disposed in the peripheral area PA.

In an embodiment, each of the first sensing electrodes IE1-1, IE1-2, IE1-3, IE1-4, IE1-5 may include first sensing parts SP1 and first connecting parts CP1. The first sensing parts SP1 in one first sensing electrode may be arranged along a first direction DR1. Each of the first connecting parts CP1 may connect adjacent first sensing parts (e.g., in the first direction DR1) to each other.

In an embodiment, each of the second sensing electrodes IE2-1, IE2-2, IE2-3, IE2-4 may include second sensing parts SP2 and second connecting parts CP2. The second sensing parts SP2 in one second sensing electrode may be arranged along a second direction DR2. Each of the second connecting parts CP2 may connect adjacent second sensing parts (e.g., in the second direction DR2) to each other.

In an embodiment, the first sensing parts SP1 and the second sensing parts SP2 may have a mesh shape.

The first sensing electrodes IE1-1, IE1-2, IE1-3, IE1-4, IE1-5 and the second sensing electrodes IE2-1, IE2-2, IE2-3, IE2-4 may include metal material. For example, in an embodiment the first sensing electrodes IE1-1, IE1-2, IE1-3, IE1-4, IE1-5 and the second sensing electrodes IE2-1, IE2-2, IE2-3, IE2-4 may include aluminum (Al), titanium (Ti), copper (Cu), molybdenum (Mo), or the like. For example, in an embodiment the first sensing electrodes IE1-1, IE1-2, IE1-3, IE1-4, IE1-5 and the second sensing electrodes IE2-1, IE2-2, IE2-3, IE2-4 may include copper (Cu).

The first sensing lines TSL1-1, TSL1-2, TSL1-3, TSL1-4, TSL1-5 may be connected to the first sensing electrodes IE1-1, IE1-2, IE1-3, IE1-4, IE1-5. The second sensing lines TSL2-1, TSL2-2, TSL2-3, TSL2-4 may be connected to the second sensing electrodes IE2-1, IE2-2, IE2-3, IE2-4.

In an embodiment, each of the first sensing lines TSL1-1, TSL1-2, TSL1-3, TSL1-4, TSL1-5 and the second sensing lines TSL2-1, TSL2-2, TSL2-3, TSL2-4 may include a line part TSL-L and a pad part TSL-P. The pad part TSL-P may be aligned in the pad area PDA. The pad part TSL-P may overlap the dummy pad IS-DPD of FIG. 3.

In an embodiment, the first sensing electrodes IE1-1, IE1-2, IE1-3, IE1-4, IE1-5 may operate as a sensing electrode (Rx), and the second sensing electrodes IE2-1, IE2-2, IE2-3, IE2-4 may operate as a driving electrode (Tx).

In an embodiment shown in FIG. 6, the input sensing layer ISU includes five first sensing electrodes and four second sensing electrodes. However, embodiments of the present disclosure are not necessarily limited thereto. For example, in some embodiments the input sensing layer ISU may include four or less or six or more first sensing electrodes, and three or less or five or more second sensing electrodes.

Additionally, in FIG. 3, the first sensing parts SP1 and the second sensing parts SP2 are illustrated as having a diamond shape (e.g., in a plan view). However, embodiments of the present disclosure are not necessarily limited thereto. For example, each of the first sensing parts SP1 and the second sensing parts SP2 may have various polygonal shapes other than a diamond (e.g., in a plan view).

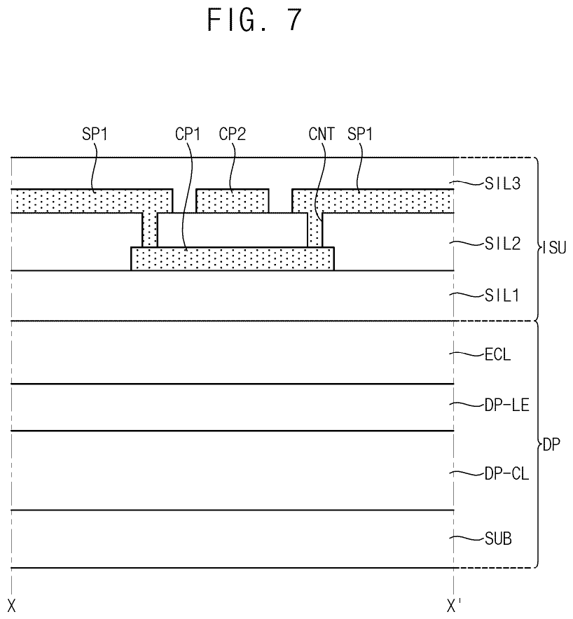

FIG. 7 is a cross-sectional view illustrating an example taken along line X-X′ of FIG. 6.

Referring to FIG. 7, in an embodiment the input sensing layer ISU may include a first sensing insulating layer SIL1, a second sensing insulating layer SIL2, and a third sensing insulating layer SIL3. The first sensing insulating layer SIL1, the second sensing insulating layer SIL2, and the third sensing insulating layer SIL3 may be sequentially stacked on the encapsulation layer ECL (e.g., in a vertical direction perpendicular to the first and second directions DR1, DR2). In an embodiment, each of the first sensing insulating layer SIL1, the second sensing insulating layer SIL2, and the third sensing insulating layer SIL3 may include an inorganic insulating material or an organic insulating material.

In an embodiment, the first connecting parts CP1 may be disposed on (e.g., disposed directly thereon) the first sensing insulating layer SIL1, and the second sensing insulating layer SIL2 may cover the first connecting parts CP1. Additionally, the first sensing parts SP1 and the second connecting parts CP2 may be disposed on (e.g., disposed directly thereon) the second sensing insulating layer SIL2. In an embodiment, the first sensing parts SP1 may be electrically connected to the first connecting parts CP1 through a contact hole CNT. Additionally, in an embodiment the second sensing parts SP2 may be disposed on the second sensing insulating layer SIL2. The third sensing insulating layer SIL3 may cover the first sensing parts SP1, the second sensing parts SP2, and the second connecting parts CP2.

However, embodiments of the present disclosure are not necessarily limited thereto, and layers on which the first sensing parts SP1, the second sensing parts SP2, the first connecting parts CP1, and the second connecting parts CP2 are disposed may be changed in various ways depending on embodiments.

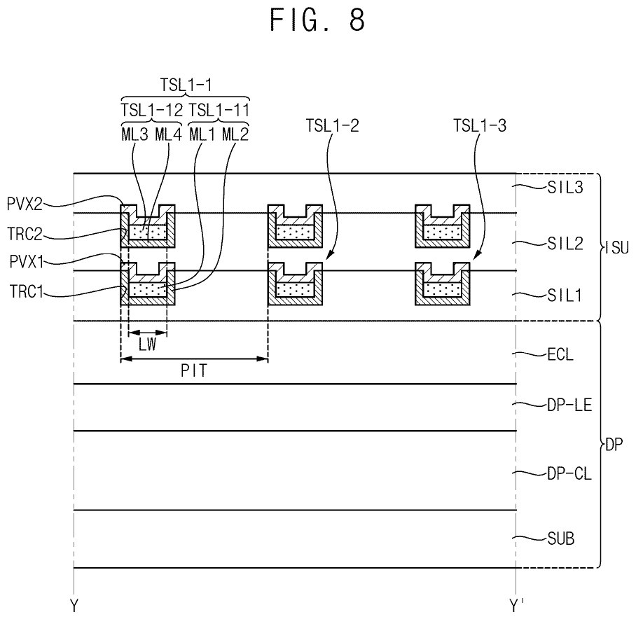

FIG. 8 is a cross-sectional view illustrating an example taken along line Y-Y′ of FIG. 6.

In FIG. 8, three first sensing lines TSL1-1, TSL1-2, TSL1-3 among the first sensing lines TSL1-1, TSL1-2, TSL1-3, TSL1-4, TSL1-5 are selectively illustrated. In an embodiment, the first sensing lines TSL1-1, TSL1-2, TSL1-3 illustrated in FIG. 8 may have the same structure as each other. In addition, first sensing lines TSL1-4, TSL1-5 and second sensing lines TSL2-1, TSL2-2, TSL2-3, TSL2-4 not illustrated in FIG. 8 may also have the same structure as the first sensing lines TSL1-1, TSL1-2, and TSL1-3 illustrated in FIG. 8. Hereinafter, a structure of the sensing line according to embodiments of the present disclosure will be described in more detail, focusing on a first sensing line TSL1-1.

Referring to FIGS. 6 and 8, in an embodiment, the first sensing line TSL1-1 may include a lower sensing line TSL1-11 and an upper sensing line TSL1-12. In an embodiment, the lower sensing line TSL1-11 and the upper sensing line TSL1-12 may be connected to each other through a contact hole. For example, the lower sensing line TSL1-11 and the upper sensing line TSL1-12 may be connected to each other (e.g., directly connected thereto) through at least one contact hole formed in the second sensing insulating layer SIL2. For example, in an embodiment, the first sensing line TSL1-1 may have a dual line structure in which two lines are connected to each other through a contact hole. Accordingly, a resistance of the first sensing line TSL1-1 may be reduced.

However, embodiments of the present disclosure are not necessarily limited thereto, and in some embodiments either the lower sensing line TSL1-11 or the upper sensing line TSL1-12 may be omitted. For example, in an embodiment the first sensing line TSL1-1 may have a single line structure. For example, the lower sensing line TSL1-11 itself may be the first sensing line TSL1-1, or the upper sensing line TSL1-12 itself may be the first sensing line TSL1-1.

Hereinafter, for convenience of description, the description will focus on an example of a double line structure in which the first sensing line TSL1-1 includes the lower sensing line TSL1-11 and the upper sensing line TSL1-12 connected to each other through a contact hole.

The first sensing insulating layer SIL1 may include a first trench pattern TRC1. The first trench pattern TRC1 may be defined by being recessed (e.g., in the vertical direction) from an upper surface of the first sensing insulating layer SIL1. For example, the first trench pattern TRC1 may be defined to be recessed from the upper surface of the first sensing insulating layer SIL1 to a point inside the first sensing insulating layer SIL1 between the upper surface of the first sensing insulating layer SIL1 and a lower surface of the first sensing insulating layer SIL1. For example, in an embodiment the first trench pattern TRC1 may be defined by arranging a plurality of first trenches, and the first trenches do not entirely penetrate the first sensing insulating layer SIL1 but penetrate only a portion of the first sensing insulating layer SIL1 (e.g., partially penetrate in the vertical direction).

The lower sensing line TSL1-11 may be disposed in the first trench pattern TRC1. For example, in an embodiment lower sensing lines of the first sensing lines TSL1-1, TSL1-2, TSL1-3, TSL1-4, TSL1-5 and the second sensing lines TSL2-1, TSL2-2, TSL2-3, TSL2-4 may be selectively disposed at positions where the first trench pattern TRC1 is defined. For example, in an embodiment the lower sensing lines of the first sensing lines TSL1-1, TSL1-2, TSL1-3, TSL1-4, TSL1-5 and the second sensing lines TSL2-1, TSL2-2, TSL2-3, TSL2-4 may be arranged one by one to correspond to the first trenches of the first trench pattern TRC1.

In an embodiment, the lower sensing line TSL1-11 may include a first metal layer ML1 and a second metal layer ML2.

The first metal layer ML1 may be disposed in the first trench pattern TRC1. For example, with respect to the upper surface of the encapsulation layer ECL, a level of an upper surface of the first metal layer ML1 may be lower than a level of the upper surface of the first sensing insulating layer SIL1. For example, the first metal layer ML1 may be positioned below the upper surface of the first sensing insulating layer SIL1 (e.g., in the vertical direction). However, embodiments of the present disclosure are not necessarily limited thereto. For example, in an embodiment, with respect to the upper surface of the encapsulation layer ECL, the level of the upper surface of the first metal layer ML1 may be the same as the level of the upper surface of the first sensing insulating layer SIL1 (e.g., in the vertical direction). In an embodiment, the first metal layer ML1 may not protrude above the upper surface of the first sensing insulating layer SIL1. For example, the first metal layer ML1 may be arranged to fill at least a portion of an empty space created by the first trench pattern TRC1.

In an embodiment, the first metal layer ML1 may include a metal material such as copper (Cu) or aluminum (Al). For example, the first metal layer ML1 may include copper (Cu). In an embodiment, the first metal layer ML1 includes copper (Cu), a resistance of the lower sensing line TSL1-11 may be further reduced.

As the first metal layer ML1 is disposed in the first trench pattern TRC1, the first metal layer ML1 may be more easily implemented as a fine pattern. For example, a line width LW of the first metal layer ML1 may be reduced. For example, in an embodiment the line width LW of the first metal layer ML1 may be less than or equal to about 2.6 micrometers. In an embodiment, the line width LW of the first metal layer ML1 may be in a range of about 0.1 micrometers to about 2.6 micrometers. In an embodiment, the line width LW of the first metal layer ML1 may be in a range of about 0.1 micrometers to about 1.5 micrometers. Accordingly, a dead space of the display device DD may be reduced.

In a comparative embodiment in which the first metal layer ML1 is disposed in a form of an embossed pattern (a convex pattern) on the upper surface of the first sensing insulating layer SIL1, an empty space such as a skew may occur in the first metal layer ML1 due to reasons in the manufacturing process. Accordingly, it may not be easy to implement the first metal layer ML1 in a fine pattern. However, according to an embodiment of the present disclosure, the first metal layer ML1 may be disposed in the first trench pattern TRC1. For example, the first metal layer ML1 may be disposed in an engraved pattern (a concaved pattern) rather than an embossed pattern (a convex pattern) in relation to the first sensing insulating layer SIL1. Accordingly, during a process of forming the first metal layer ML1, an empty space such as a skew may not be generated in the first metal layer ML1. Accordingly, the first metal layer ML1 nay be more easily implemented as a fine pattern.

In addition, as the line width LW of the first metal layer ML1 is reduced, an interval PIT (e.g., pitch) at which the first trenches of the first trench pattern TRC1 illustrated in FIG. 8 are repeated may be reduced. In an embodiment, the interval PIT at which the first trenches are repeated may be the same as an interval at which the lower sensing lines of the first sensing lines TSL1-1, TSL1-2, TSL1-3 are repeated. For example, as the line width LW of the first metal layer ML1 decreases, the interval at which the lower sensing lines of the first sensing lines TSL1-1, TSL1-2, TSL1-3 are repeated may be reduced.

For example, in an embodiment, the interval PIT at which the first trenches of the first trench pattern TRC1 are repeated may be less than or equal to about 4.0 micrometers. For example, in an embodiment the interval PIT at which the first trenches are repeated may be in a range of about 1.0 micrometers to about 4.0 micrometers. For example, in an embodiment the interval PIT at which the first trenches are repeated may be in a range of about 1.0 micrometers to about 3.0 micrometers. Accordingly, the dead space of the display device DD may be reduced.

As a method of reducing the interval at which the lower sensing lines of the first sensing lines TSL1-1, TSL1-2, TSL1-3 are repeated, a method of increasing a resolution of exposure equipment and repeatedly arranging adjacent lower sensing lines at a narrow distance may be considered. However, since there is a limit to the resolution of the exposure equipment, there is a limit to reducing the interval at which the lower sensing lines are repeated through this method. As described above, according to embodiments of the present disclosure, as the first metal layer ML1 is disposed in the first trench pattern TRC1, the first metal layer ML1 may be more easily implemented as a fine pattern. Accordingly, regardless of the resolution of the exposure equipment, the interval at which the lower sensing lines of the first sensing lines TSL1-1, TSL1-2, TSL1-3 are repeated may be reduced. Accordingly, the dead space of the display device DD may be reduced.

The second metal layer ML2 may be disposed in the first trench pattern TRC1. For example, the second metal layer ML2 may surround an inner surface of the first sensing insulating layer SIL1 defining the first trench pattern TRC1.

The second metal layer ML2 may cover a side surface (e.g., lateral sides) of the first metal layer ML1 and a lower surface of the first metal layer ML1. In an embodiment, the second metal layer ML2 may have a u-shape in a cross-sectional view. Accordingly, the second metal layer ML2 may protect the first metal layer ML1 from corrosion, or the like. Additionally, the second metal layer ML2 may increase a color sense caused by the first metal layer ML1 and reduce external light reflection by the first metal layer ML1.

In an embodiment, the second metal layer ML2 may include a different material from the first metal layer ML1. For example, the first metal layer ML1 may include a first metal material, and the second metal layer ML2 may include a second metal material different from the first metal material. In an embodiment, the first metal material may be copper (Cu), and the second metal material may be titanium (Ti). However, embodiments of the present disclosure are not necessarily limited thereto.

In an embodiment, a first protection pattern PVX1 covering an upper surface of the first metal layer ML1 may be disposed on (e.g., disposed directly thereon) the first metal layer ML1. For example, the first protection pattern PVX1 may be disposed on (e.g., disposed directly thereon) the lower sensing line TSL1-11, and the first protection pattern PVX1 may cover the lower sensing line TSL1-11. The first protection pattern PVX1 may be selectively disposed at a position where the first trench pattern TRC1 is defined. The first protection pattern PVX1 may protect the lower sensing line TSL1-11 (e.g., the first metal layer ML1) from the outside (e.g., the external environment). In an embodiment, the first protection pattern PVX1 may include an inorganic insulating material.

The first metal layer ML1, the second metal layer ML2, and the first protection pattern PVX1 may directly contact each other. The first protection pattern PVX1 may directly contact upper surfaces of the first metal layer ML1 and the second metal layer ML2 as well as a portion of the interior side surfaces of the second metal layer ML2 that is exposed by the first metal layer ML1. For example, the second metal layer ML2 and the first protection pattern PVX1 may directly contact each other, and accordingly, the first metal layer ML1 may be sealed by the second metal layer ML2 and the first protection pattern PVX1. Accordingly, damage to the first metal layer ML1 may be further reduced or prevented.

The second sensing insulating layer SIL2 may be disposed on the first sensing insulating layer SIL1, the lower sensing line TSL1-11, and the first protection pattern PVX1.

In an embodiment, the second sensing insulating layer SIL2 may define a second trench pattern TRC2. The second trench pattern TRC2 may be defined by being recessed from an upper surface of the second sensing insulating layer SIL2 (e.g., in the vertical direction). For example, the second trench pattern TRC2 may be defined to be recessed from the upper surface of the second sensing insulating layer SIL2 to a point inside the second sensing insulating layer SIL2 between the upper surface of the second sensing insulating layer SIL2 and a lower surface of the second sensing insulating layer SIL2. For example, in an embodiment the second trench pattern TRC2 may be defined by arranging a plurality of second trenches, and the second trenches do not entirely penetrate the second sensing insulating layer SIL2 but penetrate only a portion of the second sensing insulating layer SIL2 (e.g., in the vertical direction).

The upper sensing line TSL1-12 may be disposed in the second trench pattern TRC2. For example, in an embodiment, upper sensing lines of the first sensing lines TSL1-1, TSL1-2, TSL1-3, TSL1-4, TSL1-5 and the second sensing lines TSL2-1, TSL2-2, TSL2-3, TSL2-4 may be selectively disposed at positions where the second trench pattern TRC2 is defined. For example, in an embodiment the upper sensing lines of the first sensing lines TSL1-1, TSL1-2, TSL1-3, TSL1-4, TSL1-5 and the second sensing lines TSL2-1, TSL2-2, TSL2-3, TSL2-4 may be arranged one by one to correspond to the second trenches of the second trench pattern TRC2.

In an embodiment, the upper sensing line TSL1-12 may include a third metal layer ML3 and a fourth metal layer ML4.

The third metal layer ML3 may be disposed in the second trench pattern TRC2. For example, with respect to the upper surface of the encapsulation layer ECL, a level of an upper surface of the third metal layer ML3 may be lower than a level of the upper surface of the second sensing insulating layer SIL2. For example, the third metal layer ML3 may be positioned below the upper surface of the second sensing insulating layer SIL2. However, embodiments of the present disclosure are not necessarily limited thereto. For example, in an embodiment with respect to the upper surface of the encapsulation layer ECL, the level of the upper surface of the third metal layer ML3 may be the same as the level of the upper surface of the second sensing insulating layer SIL2. In an embodiment, the third metal layer ML3 may not protrude above the upper surface of the second sensing insulating layer SIL2. For example, the third metal layer ML3 may be arranged to fill at least a portion of an empty space created by the second trench pattern TRC2.

In an embodiment, the third metal layer ML3 may include a metal material such as copper (Cu) or aluminum (Al). For example, the third metal layer ML3 may include copper (Cu). In an embodiment in which the third metal layer ML3 includes copper (Cu), a resistance of the upper sensing line TSL1-12 may be further reduced.

As the third metal layer ML3 is disposed in the second trench pattern TRC2, the third metal layer ML3 may be more easily implemented as a fine pattern. For example, a line width LW of the third metal layer ML3 may be reduced. In an embodiment, the line width LW of the third metal layer ML3 may be less than or equal to about 2.6 micrometers. For example, the line width LW of the third metal layer ML3 may be in a range of about 0.1 micrometers to about 2.6 micrometers. For example, the line width LW of the third metal layer ML3 may be in a range of about 0.1 micrometers to about 1.5 micrometers. Accordingly, a dead space of the display device DD may be reduced.

Like the first metal layer ML1, as the third metal layer ML3 is disposed in an engraved pattern rather than an embossed pattern in relation to the second sensing insulating layer SIL2, during a process of forming the third metal layer ML3, an empty space such as a skew may not be generated in the third metal layer ML3. Accordingly, the third metal layer ML3 nay be more easily implemented as a fine pattern.

In addition, as the line width LW of the third metal layer ML3 decreases, an interval PIT (e.g., pitch) at which the second trenches of the second trench pattern TRC2 illustrated in FIG. 8 are repeated may be reduced. In an embodiment, the interval PIT at which the second trenches are repeated may be the same as an interval at which the upper sensing lines of the first sensing lines TSL1-1, TSL1-2, TSL1-3 are repeated. For example, as the line width LW of the third metal layer ML3 decreases, the interval at which the upper sensing lines of the first sensing lines TSL1-1, TSL1-2, TSL1-3 are repeated may be reduced.

For example, in an embodiment the interval PIT at which the second trenches of the second trench pattern TRC2 are repeated may be less than or equal to about 4.0 micrometers. For example, in an embodiment the interval PIT at which the second trenches are repeated may be in a range of about 1.0 micrometers to about 4.0 micrometers. For example, in an embodiment the interval PIT at which the second trenches are repeated may be in a range of about 1.0 micrometers to about 3.0 micrometers. Accordingly, the dead space of the display device DD may be reduced.

Like the first metal layer ML1, as the third metal layer ML3 is disposed in the second trench pattern TRC2, the third metal layer ML3 may be more easily implemented as a fine pattern. Accordingly, regardless of the resolution of the exposure equipment, the interval at which the upper sensing lines of the first sensing lines TSL1-1, TSL1-2, TSL1-3 are repeated may be reduced. Accordingly, the dead space of the display device DD may be reduced.

The fourth metal layer ML4 may be disposed in the second trench pattern TRC2. For example, the fourth metal layer ML4 may surround an inner surface of the second sensing insulating layer SIL2 defining the second trench pattern TRC2.

The fourth metal layer ML4 may cover a side surface (e.g., lateral sides) of the third metal layer ML3 and a lower surface of the third metal layer ML3. In an embodiment, the fourth metal layer ML4 may have a u-shape in a cross-sectional view. Accordingly, the fourth metal layer ML4 may protect the third metal layer ML3 from corrosion, or the like. Additionally, the fourth metal layer ML4 may increase a color sense caused by the third metal layer ML3 and reduce external light reflection by the third metal layer ML3.

In an embodiment, the fourth metal layer ML4 may include a different material from the third metal layer ML3. For example, the third metal layer ML3 may include a third metal material, and the fourth metal layer ML4 may include a fourth metal material different from the third metal material. In an embodiment, the third metal material may be copper (Cu), and the fourth metal material may be titanium (Ti). However, embodiments of the present disclosure are not necessarily limited thereto.

In an embodiment, a second protection pattern PVX2 covering an upper surface of the third metal layer ML3 may be disposed on (e.g., disposed directly thereon) the third metal layer ML3. For example, the second protection pattern PVX2 may be disposed on the upper sensing line TSL1-12, and the second protection pattern PVX2 may cover the upper sensing line TSL1-12. The second protection pattern PVX2 may be selectively disposed at a position where the second trench pattern TRC2 is defined. The second protection pattern PVX2 may protect the upper sensing line TSL1-12 (e.g., the third metal layer ML3) from the outside (e.g., the external environment). In an embodiment, the second protection pattern PVX2 may include an inorganic insulating material.

In an embodiment, the third metal layer ML3, the fourth metal layer ML4, and the second protection pattern PVX2 may directly contact each other. For example, the fourth metal layer ML4 and the second protection pattern PVX2 may directly contact each other, and accordingly, the third metal layer ML3 may be sealed by the fourth metal layer ML4 and the second protection pattern PVX2. Accordingly, damage to the third metal layer ML3 may be further reduced or prevented.

The third sensing insulating layer SIL3 may be disposed on the second sensing insulating layer SIL2, the upper sensing lines TSL1-12, and the second protection pattern PVX2.

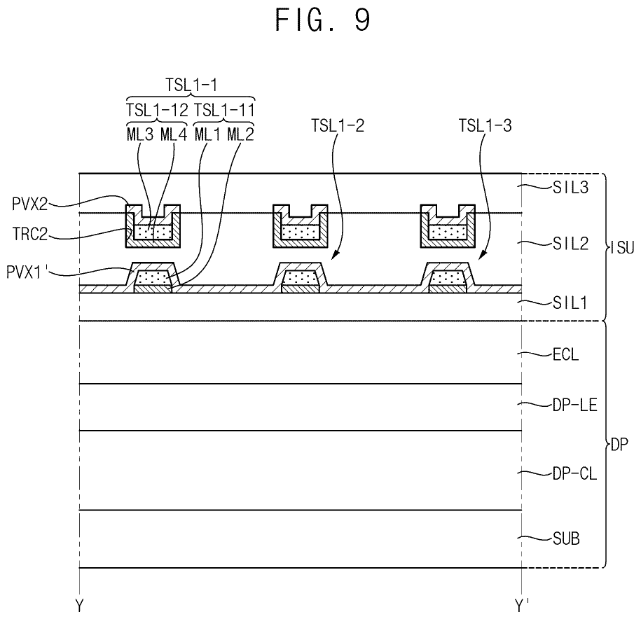

FIG. 9 is a cross-sectional view illustrating an example taken along line Y-Y′ of FIG. 6.

Referring to FIGS. 6 and 9, in an embodiment, the first trench pattern (TRC1 in FIG. 8) may be omitted. For example, in an embodiment, the lower sensing line TSL1-11 may be disposed in a form of an embossed pattern on the upper surface of the first sensing insulating layer SIL1, and the upper sensing line TSL1-12 may be disposed in a form of an engraved pattern as described with reference to FIG. 8. For example, in an embodiment a lower surface of the lower sensing line TSL1-11 may be disposed directly on an upper surface of the first sensing insulating layer SIL1.

In this embodiment, the first metal layer ML1 and the second metal layer ML2 may be sequentially stacked on an upper surface of the first sensing insulating layer SIL1 (e.g., in the vertical direction), and a first protection layer PVX1′ which entirely covers the lower sensing line TSL1-11 may be disposed on the first sensing insulating layer SIL1 and the lower sensing line TSL1-11. In an embodiment, the first protection layer PVX1′ may include an inorganic insulating material.

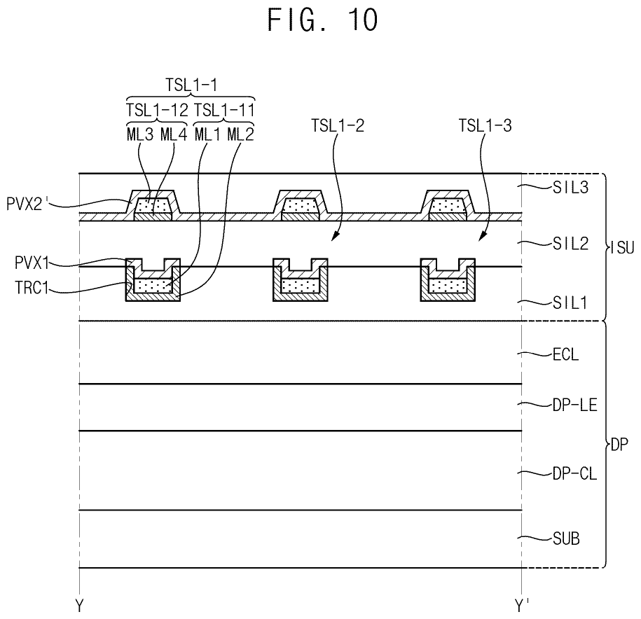

FIG. 10 is a cross-sectional illustrating an example taken along line Y-Y′ of FIG. 6.

Referring to FIGS. 6 and 10, in an embodiment, the second trench pattern (TRC2 in FIG. 8) may be omitted. For example, in an embodiment, the upper sensing line TSL1-12 may be disposed in a form of an embossed pattern on the upper surface of the second sensing insulating layer SIL2, and the lower sensing line TSL1-11 may be disposed in a form of an engraved pattern as described with reference to FIG. 8. For example, in an embodiment, a lower surface of the upper sensing line TSL1-12 may be disposed directly on an upper surface of the second sensing insulating layer SIL2.

In this embodiment, the third metal layer ML3 and the fourth metal layer ML4 may be sequentially stacked on the second sensing insulating layer SIL2 (e.g., in a vertical direction), and a second protection layer PVX2′ which entirely covers the upper sensing line TSL1-12 may be disposed on the second sensing insulating layer SIL2 and the upper sensing line TSL1-12. In an embodiment, the second protection layer PVX2′ may include an inorganic insulating material.

In an embodiment in which the sensing lines have a dual line structure in which two lines are connected through a contact hole, at least one of the lines may be arranged in a form of an engraved pattern. For example, as illustrated in FIG. 8, both the lower sensing line and the upper sensing line may be disposed in a form of an engraved pattern, or as illustrated in FIGS. 9 and 10, only one of the lower and upper sensing lines may be disposed in a form of an engraved pattern.

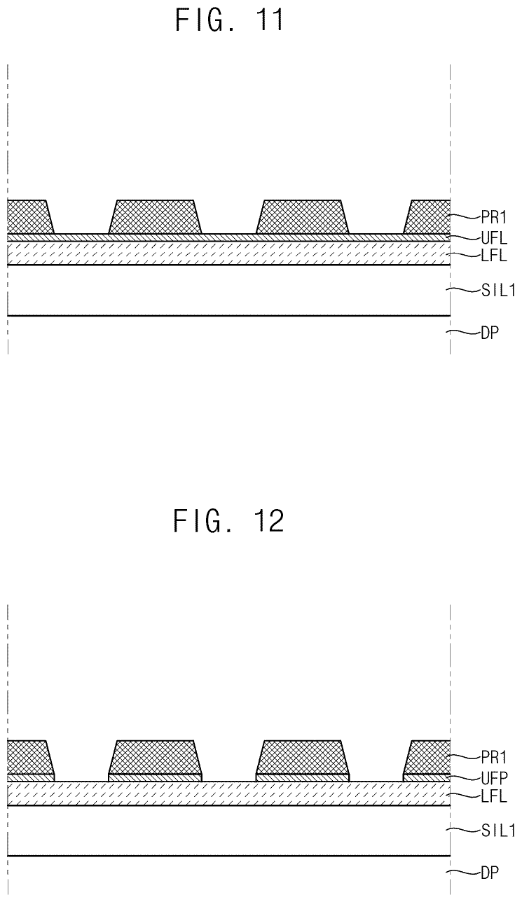

FIGS. 11 to 23 are views illustrating a manufacturing method of the sensing line of FIG. 8 according to embodiments of the present disclosure.

FIGS. 11 to 23 selectively illustrate manufacturing processes for the first sensing lines TSL1-1, TSL1-2, TSL1-3 illustrated in FIG. 8. The first sensing lines TSL1-4, TSL1-5 and the second sensing lines TSL2-1, TSL2-2, TSL2-3, TSL2-4 not illustrated in FIG. 8 may also be formed together through the manufacturing process illustrated in FIGS. 11 to 23.

Hereinafter, with reference to FIGS. 11 to 23, a method for manufacturing a sensing line according to embodiments of the present disclosure will be described, focusing on the first sensing line TSL1-1 illustrated in FIG. 8.

Referring to FIG. 11, a lower sacrificial layer LFL may be formed on (e.g., formed directly thereon) the first sensing insulating layer SIL1, an upper sacrificial layer UFL may be formed on (e.g., formed directly thereon) the lower sacrificial layer LFL, and a first photo resist pattern PR1 may be formed on (e.g., formed directly thereon) the upper sacrificial layer UFL.

The lower sacrificial layer LFL may be formed of a first material. Examples of the first material that can be used as the lower sacrificial layer LFL may include aluminum (Al), chromium (Cr), titanium (Ti), gold (Au), silver (Ag), indium tin oxide (ITO), or the like. These materials can be used alone or in combination with each other. For example, the lower sacrificial layer LFL may be formed of aluminum Al.

In an embodiment, the upper sacrificial layer UFL may be formed of a second material different from the first material. For example, the lower sacrificial layer LFL may be formed of aluminum (Al), and the upper sacrificial layer UFL may be formed of titanium (Ti). However, embodiments of the present disclosure are not necessarily limited thereto.

In an embodiment, the first photo resist pattern PRI may be formed by exposing and developing a photosensitive layer. The first photo resist pattern PRI may expose a portion of the upper sacrificial layer UFL.

Referring further to FIG. 12, an upper sacrificial pattern UFP may be formed by removing a portion of the upper sacrificial layer UFL exposed from the first photo resist pattern PR1. For example, in an embodiment the upper sacrificial layer UFL may be etched using the first photo resist pattern PR1 as a mask to form the upper sacrificial pattern UFP. In an embodiment, an etching process for forming the upper sacrificial pattern UFP may be a dry etching process. After forming the upper sacrificial pattern UFP, the upper sacrificial pattern UFP may expose a portion of the lower sacrificial layer LFL.

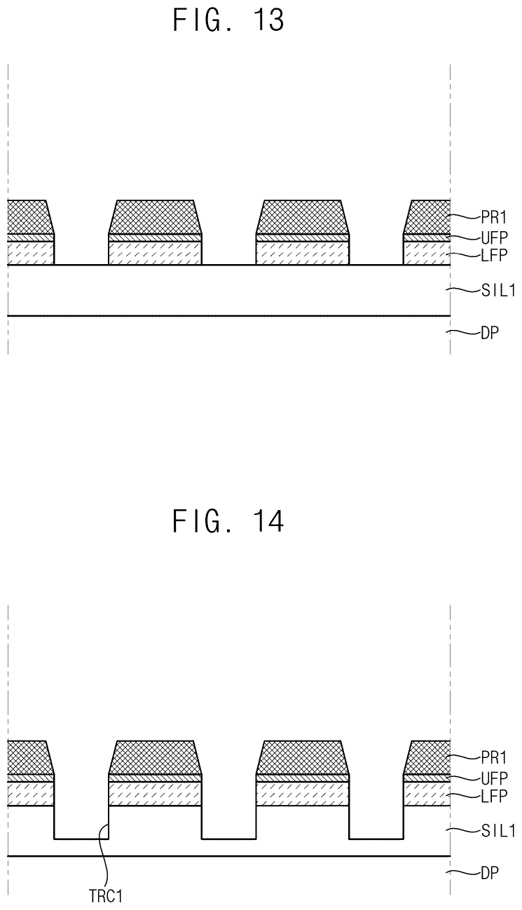

Referring further to FIG. 13, a lower sacrificial pattern LFP may be formed by removing a portion of the lower sacrificial layer LFL exposed from the upper sacrificial pattern UFP. For example, in an embodiment the lower sacrificial layer LFL may be etched using the first photo resist pattern PR1 and the upper sacrificial pattern UFP as a mask to form the lower sacrificial pattern LFP. In an embodiment, an etching process for forming the lower sacrificial pattern LFP may be a wet etching process. After forming the lower sacrificial pattern LFP, the lower sacrificial pattern LFP may expose a portion of the first sensing insulating layer SIL1.

Referring further to FIG. 14, the first trench pattern TRC1 may be formed by removing a portion of the first sensing insulating layer SIL1 exposed from the lower sacrificial pattern LFP. For example, in an embodiment the first sensing insulating layer SIL1 may be etched using the first photo resist pattern PR1, the upper sacrificial pattern UFP, and the lower sacrificial pattern LFP as a mask to form the first trench pattern TRC1. In an embodiment, an etching process for forming the first trench pattern TRC1 may be a dry etching process.

In an embodiment, as described above, the first trench pattern TRC1 may be formed to be recessed from the upper surface of the first sensing insulating layer SIL1 to a point inside the first sensing insulating layer SIL1 between the upper surface of the first sensing insulating layer SIL1 and the lower surface of the first sensing insulating layer SIL1.

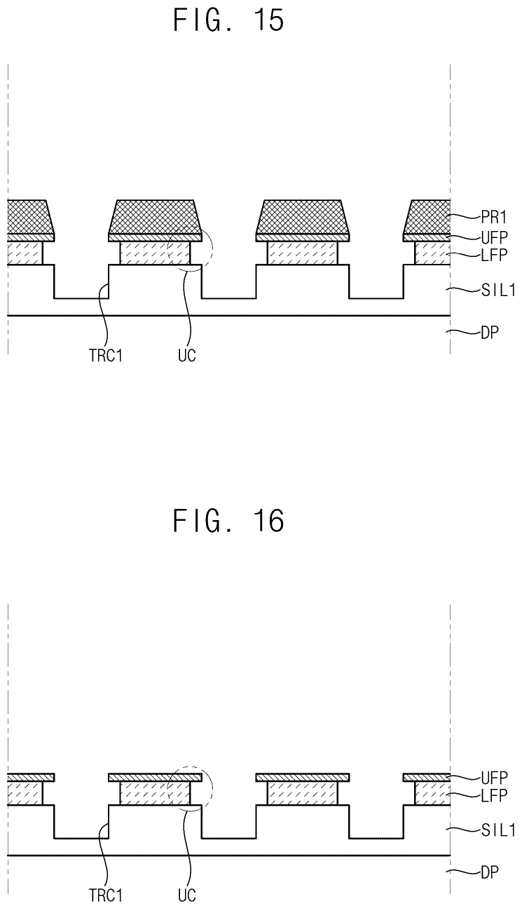

Referring to FIG. 15, in an embodiment a portion of the lower sacrificial pattern LFP may be removed to form an undercut structure UC. For example, in an embodiment the portion of the lower sacrificial pattern LFP may be removed through an etching process. In an embodiment, the etching process for forming the undercut structure UC may be a wet etching process.

In an embodiment, an etching rate (e.g., an etch rate) of the lower sacrificial pattern LFP for the etching process to form the undercut structure UC may be greater than an etching rate (e.g., an etch rate) of the upper sacrificial pattern UFP for the etching process to form the undercut structure UC. For example, in an embodiment the upper sacrificial pattern UFP may not be substantially etched by the etching process to form the undercut structure UC.

Accordingly, as illustrated in FIG. 15, a side surface of the lower sacrificial pattern LFP located inside rather than at an end of the upper sacrificial pattern UFP may be defined. Accordingly, the upper sacrificial pattern UFP may define a tip structure in relationship with the lower sacrificial pattern LFP. Accordingly, the undercut structure UC may be formed by the side surface of the lower sacrificial pattern LFP and a lower surface of the upper sacrificial pattern UFP.

Referring to FIG. 16, the first photo resist pattern PR1 may be removed. For example, in an embodiment the first photo resist pattern PR1 may be removed through a strip process. However, embodiments of the present disclosure are not necessarily limited thereto. For example, in some embodiments the etching process to form the undercut structure UC may be performed after removing the first photo resist pattern PR1.

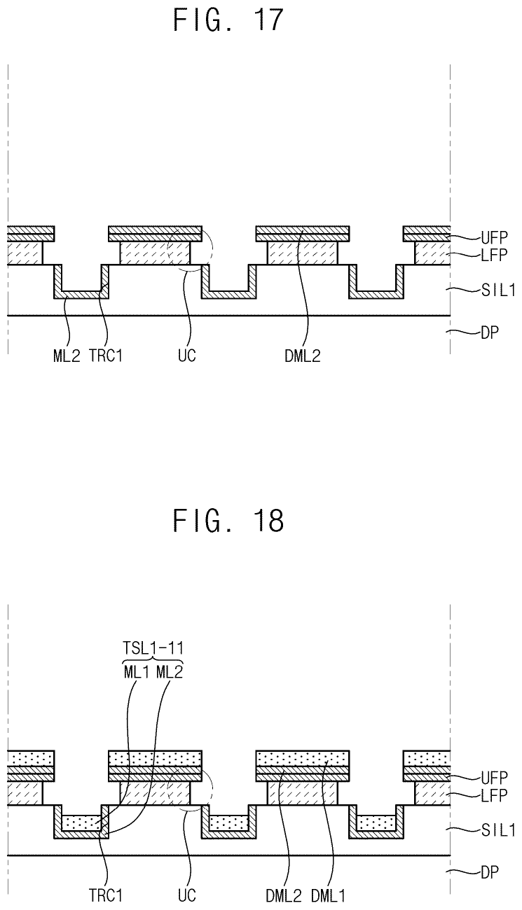

Referring to FIG. 17, the second metal layer ML2 and a second dummy metal layer DML2 may be formed. In an embodiment, the second metal layer ML2 and the second dummy metal layer DML2 may be formed through a deposition process of the second metal material. For example, in an embodiment the second metal layer ML2 and the second dummy metal layer DML2 may be formed of titanium (Ti).

Through this, the second metal layer ML2 may be formed in the first trench pattern TRC1 and the second dummy metal layer DML2 may be formed on the upper sacrificial pattern UFP. For example, in an embodiment the second metal layer ML2 and the second dummy metal layer DML2 may be formed together in the same process and may include the same material as each other. At this time, the second metal layer ML2 and the second dummy metal layer DML2 may be formed discontinuously due to the undercut structure UC. For example, the second metal layer ML2 and the second dummy metal layer DML2 may be formed to be disconnected from each other by the undercut structure UC.

Referring to FIG. 18, the first metal layer ML1 and the first dummy metal layer DML1 may be formed. In an embodiment, the first metal layer ML1 and the first dummy metal layer DML1 may be formed through a deposition process of the first metal material. For example, in an embodiment the first metal layer ML1 and the first dummy metal layer DML1 may be formed of copper (Cu).

Through this, the first metal layer ML1 may be formed in the first trench pattern TRC1 and the first dummy metal layer DML1 may be formed on (e.g., formed directly thereon) the second dummy metal layer DML2. For example, in an embodiment the first metal layer ML1 and the first dummy metal layer DML1 may be formed together in the same process and may include the same material as each other. At this time, the first metal layer ML1 and the first dummy metal layer DML1 may be formed discontinuously due to the undercut structure UC. For example, the first metal layer ML1 and the first dummy metal layer DML1 may be formed to be disconnected from each other by the undercut structure UC.

As a result, the lower sensing line TSL1-11 including the first metal layer ML1 and the second metal layer ML2 may be formed in the first trench pattern TRC1. In an embodiment, the first metal layer ML1 of the lower sensing line TSL1-11 may be formed in a form of an engraved pattern with respect to the first sensing insulating layer SIL1. For example, the first metal layer ML1 may be automatically self-patterned upon deposition by the undercut structure UC and the first trench pattern TRC1. Accordingly, a separate etching process to form the first metal layer ML1 may not be performed. Accordingly, an empty space such as skew may not be generated in the first metal layer ML1 due to the etching process. Accordingly, the first metal layer ML1 may be more easily formed into a fine pattern.

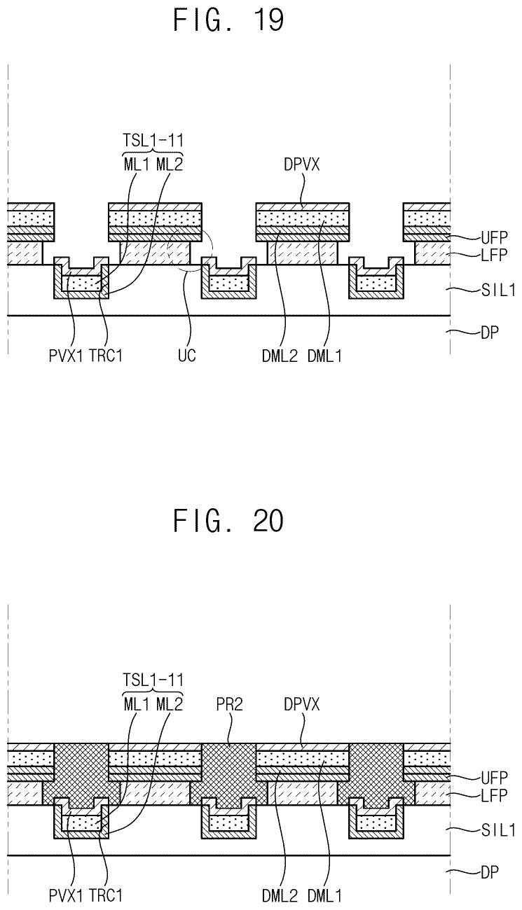

Referring to FIG. 19, the first protection pattern PVX1 and a dummy protection pattern DPVX may be formed. In an embodiment, the first protection pattern PVX1 and the dummy protection pattern DPVX may be formed through a deposition process of an inorganic insulating material.

Through this, the first protection pattern PVX1 covering the upper surface of the first metal layer ML1 may be formed on (e.g., formed directly thereon) the first metal layer ML1, and the dummy protection pattern DPVX may be formed on (e.g., formed directly thereon) the first dummy metal layer DML1. For example, the first protection pattern PVX1 and the dummy protection pattern DPVX may be formed together in the same process and may include the same material as each other. At this time, the first protection pattern PVX1 and the dummy protection pattern DPVX may be formed discontinuously due to the undercut structure UC. For example, the first protection pattern PVX1 and the dummy protection pattern DPVX may be formed to be disconnected from each other by the undercut structure UC.

Referring to FIG. 20, a second photo resist pattern PR2 may be formed. In an embodiment, the second photo resist pattern PR2 may be formed on the lower sensing line TSL1-11 and the first protection pattern PVX1. For example, the second photo resist pattern PR2 may be formed to cover the first protection pattern PVX1. For example, the second photo resist pattern PR2 may be formed on the first sensing insulating layer SIL1 to fill an empty space caused by the lower sacrificial pattern LFP, the upper sacrificial pattern UFP, the first dummy metal layer DML1, the second dummy metal layer DML2, and the dummy protection pattern DPVX. For example, in an embodiment the second photo resist pattern PR2 may be formed to expose the dummy protection pattern DPVX. In an embodiment, the second photo resist pattern PR2 may be formed by exposing and developing a photosensitive layer.

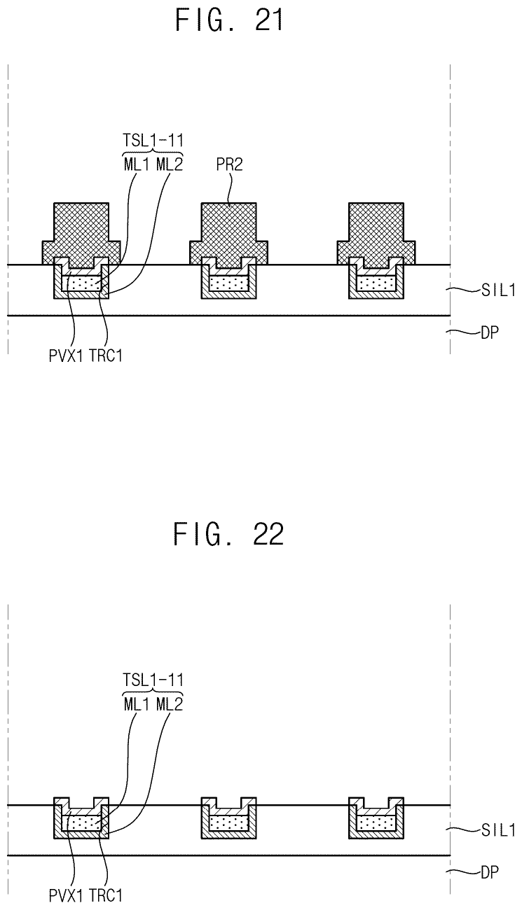

Referring further to FIG. 21, the dummy protection pattern DPVX, the first dummy metal layer DML1, the second dummy metal layer DML2, the upper sacrificial pattern UFP, and the lower sacrificial pattern LFP may be removed. For example, in an embodiment using the second photo resist pattern PR2 as a mask, the dummy protection pattern DPVX, the first dummy metal layer DML1, the second dummy metal layer DML2, the upper sacrificial pattern UFP, and the lower sacrificial pattern LFP may be etched sequentially. In an embodiment, even after the dummy protection pattern DPVX, the first dummy metal layer DML1, the second dummy metal layer DML2, the upper sacrificial pattern UFP, and the lower sacrificial pattern LFP are removed, the first metal layer ML1, the second metal layer ML2, and the first protection pattern PVX1 may remain intact below the second photo resist pattern PR2.

Referring to FIG. 22, the second photo resist pattern PR2 may be removed. For example, in an embodiment the second photo resist pattern PR2 may be removed through a strip process.

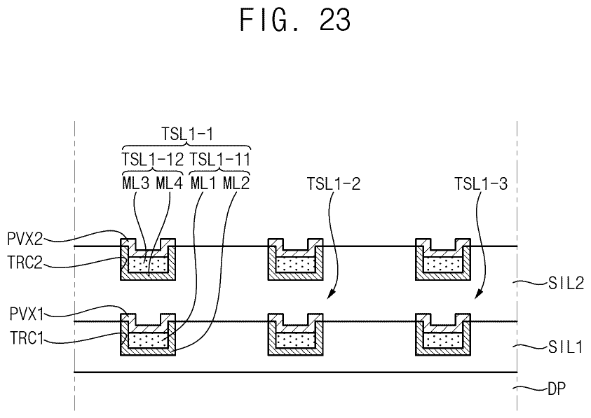

Thereafter, referring to FIG. 23, the second sensing insulating layer SIL2 may be formed on (e.g., formed directly thereon) the first sensing insulating layer SIL1. Thereafter, the upper sensing line TSL1-12 electrically connected to the lower sensing line TSL1-11 and the second protection pattern PVX2 may be formed in substantially the same manner as the manufacturing process described for the lower sensing line TSL1-11 and the first protection pattern PVX1 with reference to FIGS. 11 to 22 on the second sensing insulating layer SIL2. For example, the fourth metal layer ML4 may be formed in substantially the same manner as the manufacturing process of the second metal layer ML2 described with reference to FIG. 17, and the third metal layer ML3 may be formed may be formed in substantially the same manner as the manufacturing process of the first metal layer ML1 described with reference to FIG. 18. Additionally, the second protection pattern PVX2 may be formed in substantially the same manner as the manufacturing process of the first protection pattern PVX1 described with reference to FIG. 19. Therefore, overlapping descriptions are omitted for economy of explanation.

As a result, the first sensing lines TSL1-1, TSL1-2, TSL1-3 including a lower sensing line and an upper sensing line connected to each other through a contact hole may be formed.

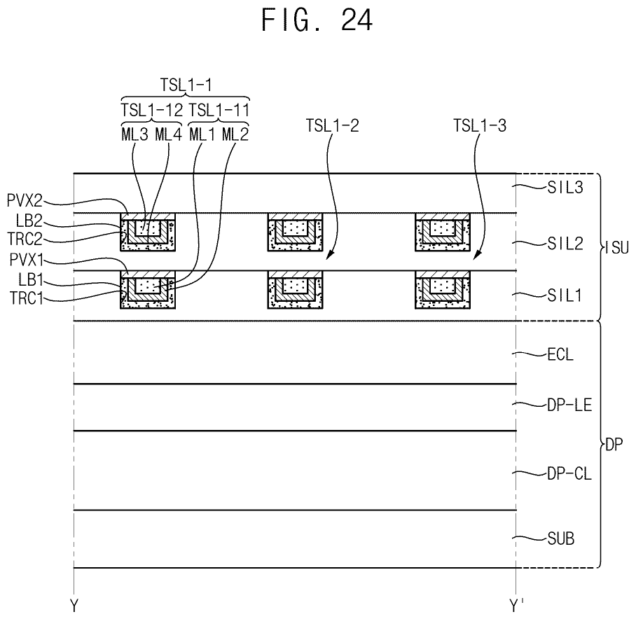

FIG. 24 is a cross-sectional view illustrating an example taken along line Y-Y′ of FIG. 6.

The input sensing layer ISU described with reference to FIG. 24 may be substantially same as the input sensing layer ISU described with reference to FIGS. 6 to 8 except for including a first blocking pattern LB1 and a second blocking pattern LB2. Therefore, overlapping descriptions are omitted for economy of explanation.

Referring to FIG. 24, in an embodiment, the input sensing layer ISU may further include the first blocking pattern LB1 and the second blocking pattern LB2.

The first light blocking pattern LB1 may be disposed in the first trench pattern TRC1. For example, the first light blocking pattern LB1 may surround the inner surface of the first sensing insulating layer SIL1 defining the first trench pattern TRC1. In an embodiment, the first light blocking pattern LB1 may have a u-shape in a cross-sectional view.

The first light blocking pattern LB1 may include a light blocking material. In an embodiment, the light blocking material may be a metal material or an organic material. An example of the metal material that can be used as the first light blocking pattern LB1 may include molybdenum-tantalum oxide (MTO). For example, the first light blocking pattern LB1 may have a three-layer structure such as MTO/Mo/MTO, MTO/Cu/MTO, and MTO/Al/MTO, and a two-layer structure such as MTO/Mo, MTO/Cu, and MTO/Al, or a MTO single-layer structure. Additionally, an example of the organic material that can be used as the first light blocking pattern LB1 may include black dye, black pigment, carbon black, or the like.

In this embodiment, the lower sensing line TSL1-11 may be disposed on (e.g., disposed directly thereon) the first light blocking pattern LB1. For example, the first light blocking pattern LB1 may cover an outer surface of the lower sensing line TSL1-11. For example, the first light blocking pattern LB1 may cover an outer surface of the second metal layer ML2. As a result, the first light blocking pattern LB1 may cover the side surface (e.g., lateral sides) of the first metal layer ML1 and the lower surface of the first metal layer ML1. Accordingly, the first light blocking pattern LB1 may increase a color sense caused by the first metal layer ML1 and reduce external light reflection by the first metal layer ML1.

In an embodiment, the first protection pattern PVX1 may cover the first light blocking pattern LB1, the first metal layer ML1, and the second metal layer ML2. The first light blocking pattern LB1, the first metal layer ML1, the second metal layer ML2, and the first protection pattern PVX1 may directly contact each other. For example, the first light blocking pattern LB1, the second metal layer ML2, and the first protection pattern PVX1 may directly contact each other, and accordingly, the first metal layer ML1 may be sealed by the first light blocking pattern LB1, the second metal layer ML2, and the first protection pattern PVX1. Accordingly, damage to the first metal layer ML1 may be further reduced or prevented.

The second light blocking pattern LB2 may be disposed in the second trench pattern TRC2. For example, the second light blocking pattern LB2 may surround the inner surface of the second sensing insulating layer SIL2 defining the second trench pattern TRC2. In an embodiment, the second light blocking pattern LB2 may have a u-shape in a cross-sectional view.

The second light blocking pattern LB2 may include a light blocking material. In an embodiment, the light blocking material may be a metal material or an organic material. An example of the metal material that can be used as the second light blocking pattern LB2 may include molybdenum-tantalum oxide (MTO). For example, the second light blocking pattern LB2 may have a three-layer structure such as MTO/Mo/MTO, MTO/Cu/MTO, and MTO/Al/MTO, and a two-layer structure such as MTO/Mo, MTO/Cu, and MTO/Al, or a MTO single-layer structure. Additionally, an example of the organic material that can be used as the second light blocking pattern LB2 may include black dye, black pigment, carbon black, or the like.

In this embodiment, the upper sensing line TSL1-12 may be disposed on (e.g., disposed directly thereon) the second light blocking pattern LB2. For example, the second light blocking pattern LB2 may cover an outer surface of the upper sensing line TSL1-12. For example, the second light blocking pattern LB2 may cover an outer surface of the fourth metal layer ML4. As a result, the second light blocking pattern LB2 may cover the side surface (e.g., lateral sides) of the third metal layer ML3 and the lower surface of the third metal layer ML3. Accordingly, the second light blocking pattern LB2 may increase a color sense caused by the third metal layer ML3 and reduce external light reflection by the third metal layer ML3.

In an embodiment, the second protection pattern PVX2 may cover the second light blocking pattern LB2, the third metal layer ML3, and the fourth metal layer ML4. The second light blocking pattern LB2, the third metal layer ML3, the fourth metal layer ML4, and the second protection pattern PVX2 may directly contact each other. For example, the second light blocking pattern LB2, the fourth metal layer ML4, and the second protection pattern PVX2 may directly contact each other, and accordingly, the third metal layer ML3 may be sealed by the second light blocking pattern LB2, the fourth metal layer ML4, and the second protection pattern PVX2. Accordingly, damage to the third metal layer ML3 may be further reduced or prevented.

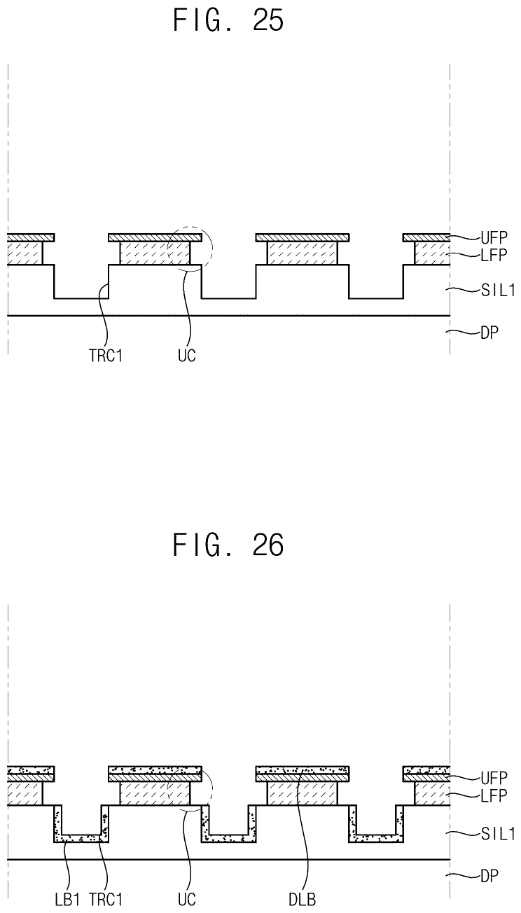

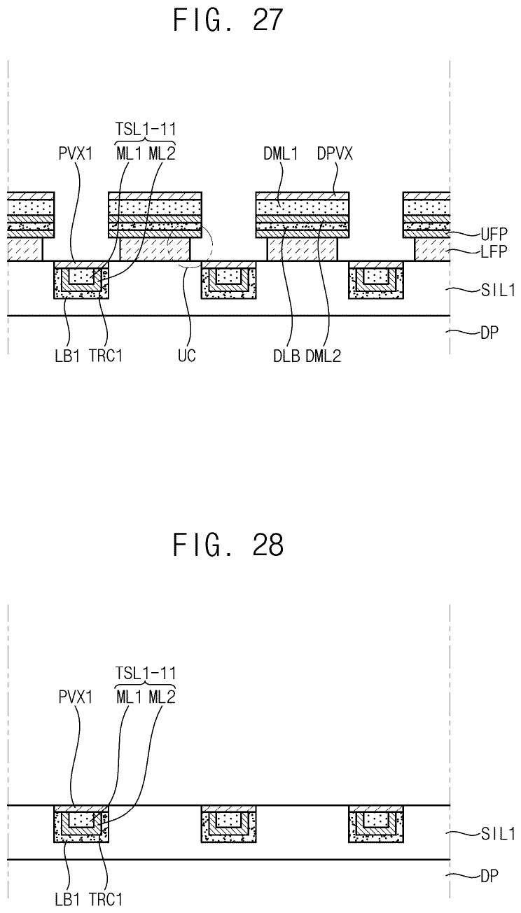

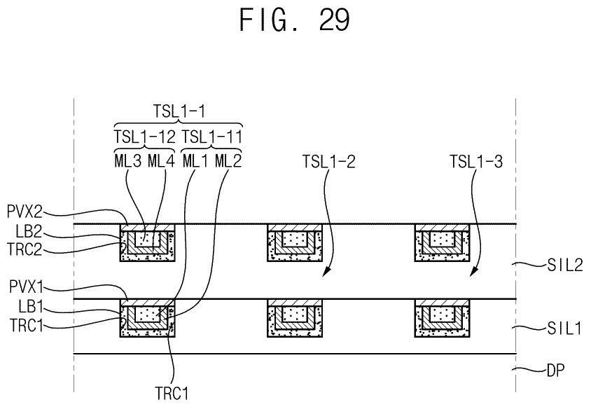

FIGS. 25 and 29 are views illustrating a manufacturing method of the sensing line of FIG. 24.

FIGS. 25 to 29 selectively illustrate manufacturing processes for the first sensing lines TSL1-1, TSL1-2, TSL1-3 illustrated in FIG. 24. The first sensing lines TSL1-4, TSL1-5 and the second sensing lines TSL2-1, TSL2-2, TSL2-3, TSL2-4 not illustrated in FIG. 24 may also be formed together through the manufacturing process illustrated in FIGS. 25 to 29.

Hereinafter, with reference to FIGS. 25 to 29, a method for manufacturing a sensing line according to embodiments of the present disclosure will be described, focusing on the first sensing line TSL1-1 illustrated in FIG. 24.

Referring to FIG. 25, the lower sacrificial pattern LFP and the upper sacrificial pattern UFP defining the undercut structure UC may be formed on the first sensing insulating layer SIL1. Additionally, the first trench pattern TRC1 may be formed in the first sensing insulating layer SIL1. This process may be performed in substantially the same manner as the manufacturing process described with reference to FIGS. 11 to 16. Therefore, overlapping descriptions are omitted for economy of explanation.

Referring to FIG. 26, the first light blocking pattern LB1 and the dummy light blocking pattern DLB may be formed. For example, in an embodiment the first light blocking pattern LB1 and the dummy light blocking pattern DLB may be formed through a deposition process of a metal material or an organic material. In an embodiment, the first light blocking pattern LB1 and the dummy light blocking pattern DLB may be formed of molybdenum-tantalum oxide (MTO).

Through this, the first light blocking pattern LB1 may be formed in the first trench pattern TRC1 and the dummy light blocking pattern DLB may be formed on (e.g., formed directly thereon) the upper sacrificial pattern UFP. For example, in an embodiment the first light blocking pattern LB1 and the dummy light blocking pattern DLB may be formed together in the same process and may include the same material as each other. At this time, the first light blocking pattern LB1 and the dummy light blocking pattern DLB may be formed discontinuously due to the undercut structure UC. For example, the first light blocking pattern LB1 and the dummy light blocking pattern DLB may be formed to be disconnected from each other by the undercut structure UC.

Referring to FIG. 27, the first metal layer ML1, the second metal layer ML2, the first protection pattern PVX1, the first dummy metal layer DML1, the second dummy metal layer DML2, and the dummy protection pattern DPVX may be formed. The first metal layer ML1 and the second metal layer ML2 may be formed in the first trench pattern TRC1, and the first protection pattern PVX1 may be formed on (e.g., formed directly thereon) the first metal layer ML1 to cover the upper surface of the first metal layer ML1. The first dummy metal layer DML1, the second dummy metal layer DML2, and the dummy protection pattern DPVX may be formed on the dummy light blocking pattern DLB. As a result, the lower sensing line TSL1-11 including the first metal layer ML1 and the second metal layer ML2 may be formed in the first trench pattern TRC1. For example, the lower sensing line TSL1-11 may be formed on the first light blocking pattern LB1. In an embodiment, the first protection pattern PVX1 may have a line shape in which an entirety of an upper surface of the first protection pattern PVX1 is positioned at a same level (e.g., in the vertical direction). This process may be performed in substantially the same manner as the manufacturing process described with reference to FIGS. 17 to 19. Therefore, overlapping descriptions are omitted for economy of explanation.

Referring further to FIG. 28, the dummy protection pattern DPVX, the first dummy metal layer DML1, the second dummy metal layer DML2, the dummy light blocking pattern DLB, the upper sacrificial pattern UFP, and the lower sacrificial pattern LFP may be removed. In an embodiment, this process may be performed in substantially the same manner as the manufacturing process described with reference to FIGS. 20 to 22, except that a process of removing the dummy light blocking pattern DLB is added. Therefore, overlapping descriptions are omitted for economy of explanation. For example, even after the dummy protection pattern DPVX, the first dummy metal layer DML1, the second dummy metal layer DML2, the dummy light blocking pattern DLB, the upper sacrificial pattern UFP, and the lower sacrificial pattern LFP are removed, the first light blocking pattern LB1, the first metal layer ML1, the second metal layer ML2, and the first protection pattern PVX1 may remain.

Thereafter, referring to FIG. 29, the second sensing insulating layer SIL2 may be formed on (e.g., formed directly thereon) the first sensing insulating layer SIL1. Thereafter, the second light blocking pattern LB2, the upper sensing line TSL1-12 electrically connected to the lower sensing line TSL1-11, and the second protection pattern PVX2 may be formed in substantially the same manner as the manufacturing process described with reference to FIGS. 25 to 28 on the second sensing insulating layer SIL2. For example, the second light blocking pattern LB2 may be formed in substantially the same manner as the manufacturing process of the first light blocking pattern LB1 described with reference to FIG. 26. In addition, the third metal layer ML3, the fourth metal layer ML4, and the second protection pattern PVX2 may be formed in substantially the same manner as the manufacturing process of the first metal layer ML1, the second metal layer ML2, and the first protection pattern PVX1 described with reference to FIG. 27. Therefore, overlapping descriptions are omitted for economy of explanation.

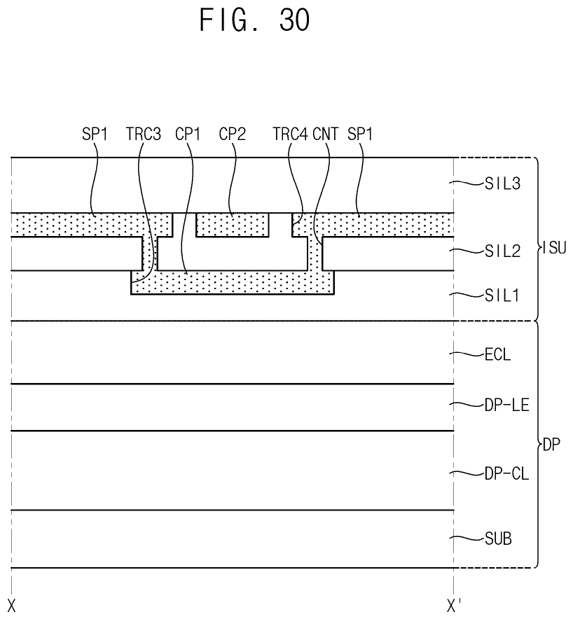

FIG. 30 is a cross-sectional view illustrating an example taken along line X-X′ of FIG.

The input sensing layer ISU described with reference to FIG. 30 may be substantially same as the input sensing layer ISU described with reference to FIGS. 6 to 8, except that the sensing parts SP1 and SP2 and the connecting parts CP1 and CP2 are disposed in the trench pattern. Therefore, overlapping descriptions are omitted.

Referring to FIG. 30, in an embodiment, the input sensing layer ISU may further define a third trench pattern TRC3 and a fourth trench pattern TRC4. For example, the first sensing insulating layer SIL1 may further define the third trench pattern TRC3, and the second sensing insulating layer SIL2 may further define the fourth trench pattern TRC4. The third trench pattern TRC3 and the fourth trench pattern TRC4 may be defined in the sensing area SA of FIG. 6.

The third trench pattern TRC3 may be formed in the same process as the first trench pattern TRC1 of FIG. 8. For example, the third trench pattern TRC3 may be defined to be recessed from the upper surface of the first sensing insulating layer SIL1 to a point inside the first sensing insulating layer SIL1 in the sensing area SA. For example, the third trench pattern TRC3 may be defined by arranging a plurality of third trenches in the sensing area SA, and the third trenches do not entirely penetrate the first sensing insulating layer SIL1 but penetrate only a portion of the first sensing insulating layer SIL1 (e.g., in the vertical direction).

The first connecting parts CP1 may be disposed in the third trench pattern TRC3. For example, the first connecting parts CP1 may not protrude above the upper surface of the first sensing insulating layer SIL1. For example, the first connecting parts CP1 may be arranged to fill at least a portion of an empty space created by the third trench pattern TRC3.

The fourth trench pattern TRC4 may be formed in the same process as the second trench pattern TRC2 of FIG. 8. For example, the fourth trench pattern TRC4 may be defined to be recessed from the upper surface of the second sensing insulating layer SIL2 to a point inside the second sensing insulating layer SIL2 in the sensing area SA. For example, the fourth trench pattern TRC4 may be defined by arranging a plurality of fourth trenches in the sensing area SA, and the fourth trenches do not entirely penetrate the second sensing insulating layer SIL2 but penetrate only a portion of the second sensing insulating layer SIL2 (e.g., in the vertical direction).

The first sensing parts SP1 and the second connecting parts CP2 may be disposed in the fourth trench pattern TRC4. Additionally, in an embodiment the second sensing parts SP2 may also be disposed in the fourth trench pattern TRC4. For example, the first sensing parts SP1, the second sensing parts SP2, and the second connecting parts CP2 may not protrude above the upper surface of the second sensing insulating layer SIL2. For example, the first sensing parts SP1, the second sensing parts SP2, and the second connecting parts CP2 may be arranged to fill at least a portion of an empty space created by the fourth trench pattern TRC4.

In an embodiment, the first sensing parts SP1, the second sensing parts SP2, the first connecting parts CP1, and the second connecting parts CP2 may be disposed in a form of an engraved pattern rather than an embossed pattern with respect to the sensing insulating layer on which each part is disposed.

In an embodiment shown in FIG. 30, the first sensing insulating layer SIL1 defines the third trench pattern TRC3 and the second sensing insulating layer SIL2 defines the fourth trench pattern TRC4 in the sensing area (SA). However, embodiments of the present disclosure are not necessarily limited thereto. For example, in some embodiments only one of the third trench pattern TRC3 and the fourth trench pattern TRC4 may be defined in the sensing area SA. For example, in an embodiment, the first connecting parts CP1 may be disposed in a form of the embossed pattern illustrated in FIG. 7, and the first sensing parts SP1, the second sensing parts SP2, and the second connecting parts CP2 may be disposed in a form of an engraved pattern. Alternatively, the first connecting parts CP1 may be disposed in a form of an engraved pattern illustrated in FIG. 30, and the first sensing parts SP1, second sensing parts SP2, and second connecting parts CP2 may be disposed in a form of an embossed pattern illustrated in FIG. 7.

In an embodiment, as described above with reference to FIG. 7, the layers on which the first sensing parts SP1, the second sensing parts SP2, the first connecting parts CP1, and the second connecting parts CP2 are arranged may be variously changed according to embodiments. For example, according to some embodiments, the trench pattern in which each of the first sensing parts SP1, the second sensing parts SP2, the first connecting parts CP1, and the second connecting parts CP2 are disposed may be determined as one of the third trench pattern TRC3 and the fourth trench pattern TRC4.

Embodiments of the present disclosure can be applied to a display panel inspection device of various display devices. For example, embodiments of the present disclosure are applicable to a display panel inspection device of various display devices such as display devices for vehicles, ships and aircraft, portable communication devices, display devices for exhibition or information transmission, medical display devices, and the like. However, embodiments of the present disclosure are not necessarily limited thereto.

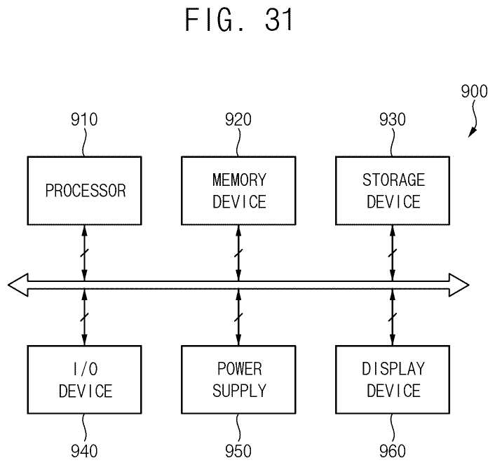

FIG. 31 is a block diagram illustrating an electronic device according to an embodiment.

Referring to FIG. 31, in an embodiment, an electronic device 900 may include a processor 910, a memory device 920, a storage device 930, an input/output (“I/O”) device 940, a power supply 950, and a display device 960. Here, the display device 960 may correspond to the display device DD of FIG. 1. The electronic device 900 may further include a plurality of ports for communicating with a video card, a sound card, a memory card, a universal serial bus (“USB”) device, or the like. In an embodiment, the electronic device 900 may be implemented as a television. In another embodiment, the electronic device 900 may be implemented as a smart phone. However, embodiments are not limited thereto, in another embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. In an embodiment, the display device 960 may be included in the I/O device 940.

The foregoing is illustrative of non-limiting embodiments of the present disclosure and is not to be construed as limiting thereof. Although a few embodiments have been described, those skilled in the art will readily appreciate that many modifications are possible in embodiments without materially departing from the novel teachings and advantages of the present disclosure. Accordingly, all such modifications are intended to be included within the scope of the present disclosure. Therefore, it is to be understood that the foregoing is illustrative of various non-limiting embodiments and the present disclosure is not to be construed as limited to the specific embodiments disclosed, and that modifications to the described embodiments, as well as other embodiments, are intended to be included within the scope of the present disclosure.

What is claimed is:

1. A display device comprising:
a light emitting element layer including a light emitting element;
an encapsulation layer disposed on the light emitting element layer and covering the light emitting element;
a sensing electrode disposed on the encapsulation layer;
a sensing insulating layer disposed on the encapsulation layer, the sensing insulating layer having an upper surface, the sensing insulating layer including a trench pattern recessed from the upper surface; and
a sensing line disposed in the trench pattern, the sensing line is connected to the sensing electrode, and includes a first metal layer.

2. The display device of claim 1, wherein with respect to an upper surface of the encapsulation layer, a level of an upper surface of the first metal layer is less than or equal to a level of the upper surface of the sensing insulating layer.

3. The display device of claim 1, wherein the first metal layer includes copper (Cu).

4. The display device of claim 1, wherein a line width of the first metal layer is less than or equal to about 2.6 micrometers.

5. The display device of claim 1, wherein an interval between at least two trenches defining the trench pattern is less than or equal to about 4.0 micrometers.

6. The display device of claim 1, wherein the sensing line is selectively disposed on the encapsulation layer at a position where the trench pattern is defined.

7. The display device of claim 1, wherein the trench pattern is recessed from the upper surface of the sensing insulating layer to a point inside the sensing insulating layer between the upper surface of the sensing insulating layer and a lower surface of the sensing insulating layer.

8. The display device of claim 1, further comprising:
a protection pattern disposed on the first metal layer and covering an upper surface of the first metal layer.

9. The display device of claim 8, wherein the protection pattern is selectively disposed on the encapsulation layer at a position where the trench pattern is defined.

10. The display device of claim 8, wherein the sensing line further includes:
a second metal layer covering a side surface of the first metal layer and a lower surface of the first metal layer and including a material different from a material of the first metal layer.

11. The display device of claim 10, wherein the first metal layer, the second metal layer, and the protection pattern are in direct contact with each other.

12. The display device of claim 1, further comprising:
a light blocking pattern disposed in the trench pattern and covering a side surface of the first metal layer and a lower surface of the first metal layer.

13. The display device of claim 12, wherein the light blocking pattern includes at least one material selected from a metal material and an organic material.

14. A method of manufacturing a display device, the method comprising:
forming a lower sacrificial layer including a first material on a sensing insulating layer, and forming an upper sacrificial layer including a second material different from the first material on the lower sacrificial layer;
forming an upper sacrificial pattern by removing a portion of the upper sacrificial layer and forming a lower sacrificial pattern by removing a portion of the lower sacrificial layer;
forming a trench pattern by removing a portion of the sensing insulating layer using the upper sacrificial pattern and the lower sacrificial pattern as a mask;
forming an undercut structure defined by the upper sacrificial pattern and the lower sacrificial pattern by removing a portion of the lower sacrificial pattern; and
forming a metal layer in the trench pattern of the sensing insulating layer.

15. The method of claim 14, wherein:
the forming of the trench pattern is performed by a first etching process;
the forming of the undercut structure is performed by a second etching process different from the first etching process; and
an etch rate of the lower sacrificial pattern for the second etching process is greater than an etch rate of the upper sacrificial pattern for the second etching process.

16. The method of claim 15, wherein:
the first etching process is a dry etching process; and
the second etching process is a wet etching process.

17. The method of claim 14, wherein the metal layer is formed of copper (Cu).

18. The method of claim 14, wherein:
in the forming of the metal layer, a dummy metal layer including a same material as the metal layer is formed on the upper sacrificial pattern, and
the dummy metal layer is formed discontinuously with the metal layer by the undercut structure.

19. The method of claim 18, further comprising:
forming a protection pattern on the metal layer covering an upper surface of the metal layer.

20. The method of claim 19, wherein:
in the forming of the protection pattern, a dummy protection pattern including a same material as the protection pattern is formed on the dummy metal layer; and
the dummy protection pattern is formed discontinuously with the protection pattern by the undercut structure.

21. The method of claim 20, further comprising:
forming a photoresist pattern that covers the protection pattern and exposes the dummy protection pattern;
removing the dummy protection pattern, the dummy metal layer, the upper sacrificial pattern, and the lower sacrificial pattern using the photoresist pattern as a mask; and
removing the photoresist pattern.

22. The method of claim 14, further comprising:
forming a light blocking pattern in the trench pattern before the forming of the metal layer, and
wherein in the forming of the light blocking pattern, a dummy light blocking pattern including a same material as the light blocking pattern is formed on the upper sacrificial pattern; and
the dummy light blocking pattern is formed discontinuously with the light blocking pattern by the undercut structure.

23. A display device comprising:
a display panel including a light emitting element layer having a light emitting element;
an input sensing layer on the display panel, the input sensing layer including sensing electrodes, sensing lines and first and second sensing insulating layers; and
each of the sensing lines includes a lower sensing line disposed on the first sensing insulating layer and an upper sensing line disposed on the second sensing insulating layer, wherein the upper and lower sensing lines are connected to each other,
wherein at least one of: the lower sensing line is arranged in an engraved pattern in an upper surface of the first sensing insulating layer and the upper sensing line is arranged in an engraved pattern in an upper surface of the second sensing insulating layer. 24 The display device of claim 23, wherein the lower sensing line is arranged in the engraved pattern in the upper surface of the first sensing insulating layer and the upper sensing line is arranged in the engraved pattern in the upper surface of the second sensing insulating layer.

25. The display device of claim 23, wherein the lower sensing line and the upper sensing line are directly connected to each other through at least one contact hole defined in the second sensing insulating layer.

26. The display device of claim 23, wherein:
the sensing electrodes include first sensing electrodes arranged along a first direction, the first sensing electrodes including first sensing parts and first connecting parts; and
the sensing electrodes further include second sensing electrodes arranged along a second direction crossing the first direction, the second sensing electrodes including second sensing parts and second connecting parts;
wherein at least some of the first sensing parts, the first connecting parts, the second sensing parts and the second connecting parts are arranged in an engraved pattern in the upper surface of the first sensing insulating layer or the upper surface of the second sensing insulating layer, respectively.

27. An electronic device comprising:
a display device; and
a power supply configured to provide power to the display device,
wherein the display device comprises:
a light emitting element layer including a light emitting element;
an encapsulation layer disposed on the light emitting element layer and covering the light emitting element;
a sensing electrode disposed on the encapsulation layer;
a sensing insulating layer disposed on the encapsulation layer, the sensing insulating layer having an upper surface, the sensing insulating layer including a trench pattern recessed from the upper surface; and
a sensing line disposed in the trench pattern, the sensing line is connected to the sensing electrode, and includes a first metal layer.
